(19) United States
(12) Patent Application Publication
(10) Pub. No.: US 2020/0311322 A1
(43) Pub. Date: Oct. 1, 2020

(54) Systems and Methods for Generating an Energy Model and Tracking Evolution of an Energy Model

(71) Applicant: Formsolver, LLC, Chicago, IL (US)

(72) Inventor: Tristan d'Estrée Sterk, Chicago, IL (US)

(21) Appl. No.: 15/998,564

(22) PCT Filed: Feb. 15, 2017
(86) PCT No.: PCT/US2017/017969

§ 371 Date: Aug. 15, 2018

Related U.S. Application Data
(60) Provisional application No. 62/295,412, filed on Feb. 15, 2016.

(51) Int. Cl. G06F 30/18; G06F 30/20; G06Q 50/06

(52) U.S. Cl. CPC G06F 30/18; G06Q 50/06; G06F 30/20

(57) ABSTRACT

Systems and methods for generating an energy model and tracking evolution of an energy model are disclosed. An example method comprises receiving material information and geometry information associated with a design model, and generating, based on the material information, geometry information, location information, and constraints, an energy analysis model associated with energy transmissions for the design model, wherein the energy transmissions are based on energy transmissions through surfaces of a plurality of model objects that collectively form the design model.

### CROSS-REFERENCE TO RELATED APPLICATION

The present disclosure is related to and claims priority to U.S. provisional patent application No. 62/295,412, filed on Feb. 15, 2016, which is incorporated herein by reference.

### TECHNICAL FIELD

Aspects of the present disclosure generally relate to processes, systems, and apparatus for representing a physical process or system by mathematical expression, modeling a physical system including devices for performing arithmetic and logical operations, modeling nonelectrical devices and systems to predict energy performance or to allow users to obtain a desired energy performance. Some aspects of the disclosure comprise tools and techniques for generating, analyzing, and tracking evolution of energy models in computer aided design (CAD). In particular, aspects of the present disclosure are directed to generating, analyzing, and tracking evolution of energy models of computer rendered designs of structures (e.g., buildings, machines, etc.) and/or features of such structures (e.g., surfaces, components, etc.). Aspects of the present disclosure also generally relate to searching for and identifying alternative features for a structure and creating a revised energy model based on the alternative features for comparison of the revised energy model with the original and other energy models of the structure.

### BACKGROUND

Energy plays an increasingly critical economic and ecological role in the design of buildings and other structures. Buildings, in particular, account for approximately 40% of the total energy consumed today worldwide and as much as one third of global greenhouse gas emissions. The design of energy efficient buildings offers opportunities to both save money and reduce the impact on the environment from unsustainable sources of energy.

Building energy modeling software is an important tool used by designers to predict the energy needs of a building. Typical software will have inputs for climate, envelope, and internal gains (e.g. occupants) and will output energy models predicting overall energy use and/or use categories (e.g. heating, cooling, lighting, etc.). Some energy modeling software import design inputs from CAD environments.

### COPYRIGHT NOTICE

A portion of the disclosure of this patent document contains material that is subject to copyright protection. The copyright owner has no objection to the facsimile reproduction by anyone of the patent document or the patent disclosure as it appears in the Patent and Trademark Office patent fie or records, but otherwise reserves all copyright rights whatsoever.

### SUMMARY

The following presents a simplified summary in order to provide a basic understanding of some aspects of the disclosure. The summary is not an extensive overview of the disclosure. It is neither intended to identify key or critical elements of the disclosure nor to delineate the scope of the disclosure. The following summary merely presents some concepts of the disclosure in a simplified form as a prelude to the description below.

Aspects of the disclosure concern devices, systems, and methods relating to generating and analyzing energy models. A computer implemented method comprises receiving material information, geometry information, location information, and constraint information associated with a design model, and generating, based on the material information, geometry information, location information, and constraint information, an energy analysis model associated with energy transmissions for the design model, wherein the energy transmissions are based on energy transmissions through surfaces of a plurality of model objects that collectively form the design model.

In some examples, the method further comprises packaging the energy transmissions into an energy profile.

In some examples, one or more portions of the energy profile are selectable by a user, wherein upon user selection, the energy profile is updated.

In some examples, the energy profile comprises at least one of a graph, text, the design profile, an index, a representation of the design model, or any combination thereof.

In some examples, the geometry information comprises at least one of area data, normal data, or vertex data associated with one or more model objects in the design model, and the material information comprises a material associated with the one or more model objects in the design model.

In some examples, the geometry information corresponds to a square wall of a building

In some examples, the material associated with the one or more model objects is brick.

In some examples, the receiving of the material information and the geometric information occurs in response to determining, at a first time, a first list of model objects within the design model, determining, at a second time, a second list corresponding to model objects that match, are altered, or are new in view of the first list of model objects, quantifying a variance based on the first list and the second list, and, determining that the quantified variance meets or exceeds a threshold.

In some examples, the receiving of the material information and the geometric information occurs in response to a manual user request.

In some examples, the method further comprises determining cost information based on the energy transmissions.

In some examples, the cost information includes at least one of material cost or energy cost.

In some examples, the material information comprises a first material, the geometry information comprises a first geometry, the energy analysis model is a first energy analysis model, and the energy transmissions are first energy transmissions, and the method further comprises locating at least one of a second material different from the first material or a second geometry different from the first geometry, generating a second energy analysis model based on the at least one of the second material or the second geometry and based on the location information and the constraints, and determining, based on the generated second energy analysis model, second energy transmissions for the design model.

In some examples, the material information is first material information, the geometry information is first geometry information, the energy analysis model is a first energy analysis model, and the energy transmissions are first energy transmissions, and the method further comprises generating a second energy analysis model based on received second material information and second geometry information, determining, based on the generated second energy analysis model, second energy transmissions for the design model, and generating, based on the first energy transmissions and the determined second energy transmissions, an energy chronology.

In some examples, the method further comprises causing the first energy transmissions and the second energy transmissions to be presented at a user device.

In some examples, the method further comprises causing the energy chronology to be presented at the user device as a plurality of bars, in response to user selection of a first one of the plurality of bars, causing presentation of a first energy profile based on the first energy transmissions, and in response to user selection of a second one of the plurality of bars, causing presentation of a second energy profile based on the second energy transmissions.

An example method comprises receiving, by a computing device remote from a user device, a design profile associated with a design model generated at the user device. In some examples, the method further comprises generating, by the computing device, an energy analysis model based on the received design profile. The example method comprises determining, by the computing device and based on the generated energy analysis model, energy transmissions for the design model.

In some examples, the receiving of the design profile occurs in response to determining that a variance in the design model satisfies a threshold.

In some examples, the receiving of the design profile occurs in response to a manual user request.

In some examples, the method further comprises packaging the determined energy transmissions into an energy profile.

In some examples, the design profile is a first design profile, the energy analysis model is a first energy analysis model, and the energy transmissions are first energy transmissions and the method further comprises generating a second energy analysis model based on a received second design profile, determining, based on the generated second energy analysis model, second energy transmissions for the design model, and generating, based on the determined first energy transmissions and the determined second energy transmissions, an energy chronology.

In some examples, the design profile comprises at least one of area data, normal data, vertex data, or material data associated with one or more model objects in the design model.

In some examples, the determining that the variance in the design profile satisfies the threshold comprises determining, at a first time, a first list of model objects within the design model, determining, at a second time, a second list corresponding to model objects that match, are altered, or are new in view of the first list of model objects, quantifying the variance based on the second list, and determining that the quantified variance meets or exceeds the threshold.

In some examples, the method further comprises determining cost information based on the energy transmissions.

In some examples, the design profile comprises a first material or a first geometry, the energy analysis model is a first energy analysis model, and the energy transmissions are first energy transmissions and the method further comprises locating at least one of a second material different from the first material or a second geometry different from the first geometry, generating a second energy analysis model based on the design profile and based on the at least one of the second material or the second geometry, and determining, based on the generated second energy analysis model, second energy transmissions for the design model.

In some examples, the method further comprises causing the first energy transmissions and the second energy transmissions to be presented at the user device.

In some examples, the locating of at least one of the second material different from the first material or the second geometry different from the first geometry comprises narrowing material search results to types of material produced by a manufacture.

In some examples, the locating of at least one of the second material different from the first material or the second geometry different from the first geometry comprises narrowing geometric search results to vertex transforms within a threshold distance.

An example apparatus comprises a first controller configured to receive a design profile associated with a design model. In some examples, a model generator is configured to generate an energy analysis model based on the received design profile. The example model generator is further configured to generate the generated energy analysis model to determine energy transmissions for the design model.

In some examples, the first controller is configured to receive the design profile in response to a second controller determining that a variance in the design model satisfies a threshold.

In some examples, the controller is configured to package the determined energy transmissions into an energy profile.

In some examples, the design profile is a first design profile, the energy analysis model is a first energy analysis model, and the energy transmissions are first energy transmissions and the model generator is configured to generate a second energy analysis model based on a received second design profile, and is configured to analyze the generated second energy analysis model to determine second energy transmissions for the design model. In some examples, the apparatus further comprises a chronology generator configured to generate, based on the determined first energy transmissions and the determined second energy transmissions, an energy chronology.

In some examples, the design profile comprises at least one of area data, normal data, vertex data, or material data associated with one or more model objects in the design model.

In some examples, to determine that the variance in the design profile satisfies the threshold, the second controller is configured to determine, at a first time, a first list of model objects within the design model, determine, at a second time, a second list corresponding to model objects that match, are altered, or are new in view of the first list of model objects, quantify the variance based on the second list, and determine that the quantified variance meets or exceeds the threshold.

In some examples, the model generator is further configured to determine cost information based on the energy transmissions.

In some examples, the design profile comprises a first material or a first geometry, the energy analysis model is a first energy analysis model, and the energy transmissions are first energy transmissions and the apparatus further comprises a search engine. The example search engine is configured to locate at least one of a second material different from the first material or a second geometry different from the first geometry. In some examples, the model generator is configured to generate a second energy analysis model based on the design profile and based on the at least one of the second material or the second geometry, and analyze the generated second energy analysis model to determine second energy transmissions for the design model.

In some examples, the apparatus further comprises a user interface configured to present to a user the first energy transmissions and the second energy transmissions.

In some examples, to locate at least one of the second material different from the first material or the second geometry different from the first geometry, the search engine is configured to narrow material search results to types of material produced by a manufacture.

In some examples, to locate at least one of the second material different from the first material or the second geometry different from the first geometry, the search engine is configured to narrow geometric search results to vertex transforms within a threshold distance.

An example system comprises a user device and a computing device remote from the user device. The example computing device comprises a first controller to receive, from a user device, a design profile associated with a design model generated at the user device. In some examples, the computing device further comprises a model generator to generate an energy analysis model based on the received design profile. The example model generator analyzes the generated energy analysis model to determine energy transmissions for the design model.

In some examples, the first controller receives the design profile in response to a second controller, at the user device, determining that a variance in the design model satisfies a threshold.

In some examples, the first controller packages the determined energy transmissions into an energy profile.

In some examples, the design profile is a first design profile, the energy analysis model is a first energy analysis model, and the energy transmissions are first energy transmissions and the model generator generates a second energy analysis model based on a received second design profile and analyzes the generated second energy analysis model to determine second energy transmissions for the design model. In some examples, the computing device further comprises a chronology generator to generate, based on the determined first energy transmissions and the determined second energy transmissions, an energy chronology.

In some examples, the design profile comprises at least one of area data, normal data, vertex data, or material data associated with one or more model objects in the design model.

In some examples, to determine that the variance in the design profile satisfies the threshold, the second controller determines, at a first time, a first list of model objects within the design model, determines, at a second time, a second list corresponding to model objects that match, are altered, or are new in view of the first list of model objects, quantifies the variance based on the second list, and determines that the quantified variance meets or exceeds the threshold.

In some examples, the model generator further determines cost information based on the energy transmissions.

In some examples, the design profile comprises a first material or a first geometry, the energy analysis model is a first energy analysis model, and the energy transmissions are first energy transmissions and the computing device further comprises a search engine to locate at least one of a second material different from the first material or a second geometry different from the first geometry. In some examples, the model generator generates a second energy analysis model based on the design profile and based on the at least one of the second material or the second geometry, and analyzes the generated second energy analysis model to determine second energy transmissions for the design model.

In some examples, the user device comprises a user interface to present the first energy transmissions and the second energy transmissions to a user.

In some examples, to locate at least one of the second material different from the first material or the second geometry different from the first geometry the search engine narrows material search results to types of material produced by a manufacture.

In some examples, to locate at least one of the second material different from the first material or the second geometry different from the first geometry, the search engine narrows geometric search results to vertex transforms within a threshold distance.

An example computer-implemented method comprises receiving first material information or first geometry information associated with a design model generated at a user device. The example method further comprises generating a first energy analysis model based on the received first material information or first geometry information. In some examples, the method includes determining, based on the generated first energy analysis model, first energy transmissions for the design model. In some examples, the method comprises locating at least one of a second material different from a first material associated with the first material information or a second geometry different from a first geometry associated with the first geometry information. In some examples, the method comprises generating a second energy analysis model based on the design profile and based on the at least one of the second material or the second geometry. The example method may further comprise determining, based on the generated second energy analysis model, second energy transmissions for the design model.

In some examples, the receiving of the first material information or first geometry information occurs in response to determining that a variance in the design model satisfies a threshold.

In some examples, the method further comprises packaging the determined first energy transmissions into a first energy profile and packaging the determined second energy transmission into a second energy profile.

In some examples, the first energy profile and the second energy profile respectively comprise at least one of a graph, text, the design profile, an index, a representation of the design model, or any combination thereof.

In some examples, the method further comprises presenting, to a user, the first energy profile, wherein the first energy transmissions are presented to a user in a line graph and as a first bar in a bar graph and the second energy transmissions are presented to the user as a second bar in the bar graph, wherein the first bar is adjacent the second bar.

In some examples, the first bar is emphasized and the method further comprises, in response to a user selecting the second bar, emphasizing the second bar and presenting the second energy transmission in the line graph.

In some examples, the method further comprises presenting the second energy transmissions to a user, receiving an indication that the user selected the second energy transmissions, and associating the at least one of the second material or the second geometry with the design profile corresponding to the design model, wherein the second material comprises an identifier of a manufacturer.

In some examples, the locating of the at least one of the second material different from the first material or the second geometry different from the first geometry comprises, determining a material constraint defining a first search space for materials, determining a geometric constraint defining a second search space for geometries, and locating the at least one of the second material or the second geometry based on the first search space and the second search space.

In some examples, the design profile is a first design profile and the method further comprises generating a third energy analysis model based on a received second design profile, determining, based on the generated third energy analysis model, third energy transmissions for the design model, and generating, based on the determined first energy transmissions and the determined third energy transmissions, an energy chronology.

In some examples, the energy chronology comprises a history of energy transmissions determined for various iterations of the design model.

In some examples, the design profile comprises at least one of area data, normal data, vertex data, or material data associated with one or more model objects in the design model.

In some examples, the determining that the variance in the design profile satisfies the threshold comprises, determining, at a first time, a first list of model objects within the design model, determining, at a second time, a second list corresponding to model objects that match, are altered, or are new in view of the first list of model objects, quantifying the variance based on the second list, and determining that the quantified variance meets or exceeds the threshold.

In some examples, the method further comprises causing the first energy transmissions, the second energy transmissions, and the third energy transmission to be presented at the user device.

An example apparatus comprises a first controller configured to receive first material information or first geometry information associated with a design model. The example apparatus further comprises a model generator configured to generate a first energy analysis model based on the received first material information or first geometry information. In some examples, the model generator is configured to analyze the generated first energy analysis model to determine first energy transmissions for the design model. In some examples, the apparatus further includes a search engine configured to locate at least one of a second material different from a first material associated with the first material information or a second geometry different from a first geometry associated with the first geometric information.

In some examples, the first controller is configured to receive the first material information or first geometry information in response to a second controller determining that a variance in the design model satisfies a threshold.

In some examples, the model generator is configured to generate a second energy analysis model based on the design profile and based on the at least one of the second material or the second geometry. The example model generator may be further configured to analyze the generated second energy analysis model to determine second energy transmissions for the design model.

In some examples, the first controller is configured to package the determined first energy transmissions and the determined second energy transmission into energy profiles.

In some examples, the design profile is a first design profile and the model generator is further configured to generate a third energy analysis model based on a received second design profile, and analyze the generated third energy analysis model to determine third energy transmissions for the design model. In some examples, the apparatus further comprises a chronology generator configured to generate, based on the determined first energy transmissions and the determined third energy transmissions, an energy chronology.

In some examples, to generate the energy chronology, the chronology generator is configured to determine a history of energy transmissions for various iterations of the design model.

In some examples, the design profile comprises at least one of area data, normal data, vertex data, or material data associated with one or more model objects in the design model.

In some examples, to determine that the variance in the design profile satisfies the threshold the second controller is configured to determine, at a first time, a first list of model objects within the design model, determine, at a second time, a second list corresponding to model objects that match, are altered, or are new in view of the first list of model objects, quantify the variance based on the second list, and determine that the quantified variance meets or exceeds the threshold.

In some examples, the apparatus further comprises a user interface to present to a user the first energy transmissions, the second energy transmissions, and the third energy transmissions.

An example system comprises a user device in communication with a computing device remote from the user device. In some examples, the computing device comprises a first controller configured to receive, from the user device, first material information or first geometry information associated with a design model generated at a user device. The example computing device further comprises a model generator configured to generate a first energy analysis model based on the received first material information or first geometry information. In some examples, the model generator is configured to analyze the generated first energy analysis model to determine first energy transmissions for the design model. In some examples, the computing device further includes a search engine configured to locate at least one of a second material different from a first material associated with the first material information or a second geometry different from a first geometry associated with the first geometric information. In some examples, the model generator is configured to generate a second energy analysis model based on the design profile and based on the at least one of the second material or the second geometry. The example model generator may be further configured to analyze the generated second energy analysis model to determine second energy transmissions for the design model.

In some examples, the first controller is configured to receive the first material information or first geometry information in response to a second controller, at the user device, determining that a variance in the design model satisfies a threshold.

In some examples, the first controller is configured to package the determined first energy transmissions and the determined second energy transmission into energy profiles.

In some examples, the design profile is a first design profile and the model generator is further configured to generate a third energy analysis model based on a received second design profile, and analyze the generated third energy analysis model to determine third energy transmissions for the design model. In some examples, the computing device further comprises a chronology generator configured to generate, based on the determined first energy transmissions and the determined third energy transmissions, an energy chronology.

In some examples, to generate the energy chronology, the chronology generator is configured to determine a history of energy transmissions for various iterations of the design model.

In some examples, the design profile comprises at least one of area data, normal data, vertex data, or material data associated with one or more model objects in the design model.

In some examples, to determine that the variance in the design profile satisfies the threshold the second controller is configured to determine, at a first time, a first list of model objects within the design model, determine, at a second time, a second list corresponding to model objects that match, are altered, or are new in view of the first list of model objects, quantify the variance based on the second list, and determine that the quantified variance meets or exceeds the threshold.

In some examples, the user device comprises a user interface to present to a user the first energy transmissions, the second energy transmissions, and the third energy.

An example method comprises receiving, by a computing device remote from a user device, a first design profile associated with a design model generated at the user device. In some examples, the method further comprises generating, by the computing device, a first energy analysis model based on the first design profile. The example method may comprise determining, by the computing device and based on the generated energy analysis model, first energy transmissions for the design model. In some examples, the method comprises, in response to receiving a second design profile, generating, based on the second design profile, a second energy analysis model. The example method further includes determining, based on the generated second energy analysis model, second energy transmissions for the design model.

In some examples, the receiving of the design profile occurs in response to determining that a variance in the design model satisfies a threshold.

In some examples, the method further comprises generating, based on the determined first energy transmissions and the determined second energy transmissions, an energy chronology.

In some examples, the method further comprises packaging the determined first energy transmissions and the determined second energy transmissions into energy profiles.

In some examples, the determining that the variance in the design profile satisfies the threshold comprises determining, at a first time, a first list of model objects within the design model, determining, at a second time, a second list corresponding to model objects that match, are altered, or are new in view of the first list of model objects, quantifying the variance based on the second list, and determining that the quantified variance meets or exceeds the threshold.

In some examples, the first design profile comprises a first material or a first geometry, and the method further comprises locating at least one of a second material different from the first material or a second geometry different from the first geometry, generating a third energy analysis model based on the first design profile and based on the at least one of the second material or the second geometry, and determining, based on the generated third energy analysis model, third energy transmissions for the design model.

In some examples, the method further comprises causing the first energy transmissions, the second energy transmissions, and the third energy transmissions to be presented at the user device.

An example apparatus comprises a first controller to receive a first design profile associated with a design model. In some examples, the apparatus further comprises a model generator to generate a first energy analysis model based on the first design profile. The example model generator is configured to analyze the generated energy analysis model to determine first energy transmissions for the design model. In some examples, in response to the first controller receiving a second design profile, the model generator is configured to generate, based on the second design profile, a second energy analysis model. The example model generator may be further configured to analyze the generated second energy analysis model to determine second energy transmissions for the design model.

In some examples, the first controller is configured to receive the first design profile in response to a second controller determining that a variance in the design model satisfies a threshold.

In some examples, the apparatus further comprises a chronology generator to generate, based on the determined first energy transmissions and the determined second energy transmissions, an energy chronology.

In some examples, the first controller is configured to package the determined first energy transmissions and the determined second energy transmissions into energy profiles.

In some examples, to determine that the variance in the design profile satisfies the threshold, the second controller is configured to determine, at a first time, a first list of model objects within the design model, determine, at a second time, a second list corresponding to model objects that match, are altered, or are new in view of the first list of model objects, quantify the variance based on the second list, and determine that the quantified variance meets or exceeds the threshold.

In some examples, the first design profile comprises a first material or a first geometry, and the apparatus further comprises a search engine configured to locate at least one of a second material different from the first material or a second geometry different from the first geometry. In such examples, the model generator may be configured to generate a third energy analysis model based on the first design profile and based on the at least one of the second material or the second geometry, and analyze the generated third energy analysis model to determine third energy transmissions for the design model.

In some examples, the apparatus further comprises a user interface to present to a user the first energy transmissions, the second energy transmissions, and the third energy transmissions device.

An example system comprises a user device and a computing device remote form the user device. In some examples, the computing device comprises a first controller to receive, from a second controller at the user device, a first design profile associated with a design model generated at the user device. In some examples, the computing device further comprises a model generator to generate a first energy analysis model based on the first design profile. The example model generator is configured to analyze the generated energy analysis model to determine first energy transmissions for the design model. In some examples, in response to the first controller receiving a second design profile from the user device, the model generator is configured to generate, based on the second design profile, a second energy analysis model. The example model generator may be further configured to analyze the generated second energy analysis model to determine second energy transmissions for the design model.

In some examples, the first controller is configured to receive the first design profile in response to the second controller determining that a variance in the design model satisfies a threshold.

In some examples, the computing device further comprises a chronology generator to generate, based on the determined first energy transmissions and the determined second energy transmissions, an energy chronology.

In some examples, the first controller is configured to package the determined first energy transmissions and the determined second energy transmissions into energy profiles.

In some examples, to determine that the variance in the design profile satisfies the threshold, the second controller is configured to determine, at a first time, a first list of model objects within the design model, determine, at a second time, a second list corresponding to model objects that match, are altered, or are new in view of the first list of model objects, quantify the variance based on the second list, and determine that the quantified variance meets or exceeds the threshold.

In some examples, the first design profile comprises a first material or a first geometry, and the computing device further comprises a search engine configured to locate at least one of a second material different from the first material or a second geometry different from the first geometry. In such examples, the model generator may be configured to generate a third energy analysis model based on the first design profile and based on the at least one of the second material or the second geometry, and analyze the generated third energy analysis model to determine third energy transmissions for the design model.

In some examples, the user device further comprises a user interface to present to a user the first energy transmissions, the second energy transmissions, and the third energy transmissions device.

An example method comprises receiving, from a first device, first material information and first geometry information corresponding to a model, receiving material constraints corresponding to the first material information and geometric constraints corresponding to the first geometry information, and locating, based on the material constraints or geometric constraints, at least one of a second material different from a first material associated with the first material information or a second geometry different from a first geometry material associated with the first geometry information.

In some examples, the locating of at least one of the second material different from the first material or the second geometry different from the first geometry is based on at least one of a genetic algorithm, a machine learning algorithm, a statistical model, or combination thereof.

In some examples, the received material constraints correspond to at least one of locked, type, sub-type, palette, or unlocked.

In some examples, the locating of the second material different from the first material comprises locating materials that are at least one of a same type, a same brand, a same manufacturer, or a same supplier as the first material.

In some examples, the locating of the second material different from the first material comprises locating materials of a type associated with the first material information.

In some examples, the locating of the second material different from the first material comprises locating materials of any type.

In some examples, the first geometry information comprises a plurality of vertices of a model object and the received geometric constraints correspond to a user selected fraction of a maximum distance from which a first vertex of the plurality of vertices of the model object may vary.

In some examples, the locating of the second geometry different from the first geometry comprises locating geometries with vertices that vary less than the user selected fraction of the maximum distance from vertices of the first geometry.

In some examples, the maximum distance corresponds to a minimum distance between each of the plurality of vertices of the model object.

An example apparatus comprises a controller to receive first material information and first geometry information corresponding to a model, and receive material constraints corresponding to the first material information and geometric constraints corresponding to the first geometry information. The example apparatus further comprises a search engine to locate, based on the material constraints or geometric constraints, at least one of a second material different from a first material associated with the first material information or a second geometry different from a first geometry material associated with the first geometry information.

In some examples, the search engine locates the at least one of the second material different from the first material or the second geometry different from the first geometry based on at least one of a genetic algorithm, a machine learning algorithm, a statistical model, or combination thereof.

In some examples, the received material constraints correspond to at least one of locked, type, sub-type, palette, or unlocked.

In some examples, to locate the second material different from the first material, the search engine locates materials that are at least one of a same type, a same brand, a same manufacturer, or a same supplier as the first material.

In some examples, to locate the second material different from the first material, the search engine locates materials of a type associated with the first material information.

In some examples, to locate the second material different from the first material, the search engine locates materials of any type.

In some examples, the first geometry information comprises a plurality of vertices of a model object and the received geometric constraints correspond to a user selected fraction of a maximum distance from which a first vertex of the plurality of vertices of the model object may vary.

In some examples, to locate the second geometry different from the first geometry, the search engine locates geometries with vertices that vary less than the user selected fraction of the maximum distance from vertices of the first geometry.

In some examples, the maximum distance corresponds to a minimum distance between each of the plurality of vertices of the model object.

An example system comprises a user device in communication with a computing device. The example computing device comprises a first controller to receive first material information and first geometry information corresponding to a model generated at the user device, and receive material constraints corresponding to the first material information and geometric constraints corresponding to the first geometry information. The example computing device further comprises a search engine to locate, based on the material constraints or geometric constraints, at least one of a second material different from a first material associated with the first material information or a second geometry different from a first geometry material associated with the first geometry information.

In some examples, the search engine locates the at least one of the second material different from the first material or the second geometry different from the first geometry based on at least one of a genetic algorithm, a machine learning algorithm, a statistical model, or combination thereof.

In some examples, the received material constraints correspond to at least one of locked, type, sub-type, palette, or unlocked selected by a user at the user device.

In some examples, to locate the second material different from the first material, the search engine locates materials that are at least one of a same type, a same brand, a same manufacturer, or a same supplier as the first material.

In some examples, to locate the second material different from the first material, the search engine locates materials of a type associated with the first material information.

In some examples, to locate the second material different from the first material, the search engine locates materials of any type.

In some examples, the first geometry information comprises a plurality of vertices of a model object and the received geometric constraints correspond to a user selected fraction of a maximum distance from which a first vertex of the plurality of vertices of the model object may vary.

In some examples, to locate the second geometry different from the first geometry, the search engine locates geometries with vertices that vary less than the user selected fraction of the maximum distance from vertices of the first geometry.

In some examples, the maximum distance corresponds to a minimum distance between each of the plurality of vertices of the model object.

An example computer-implemented method comprises receiving data corresponding to a representation of a structure comprising one or more model objects associated with material information, geometry information, and location information. In some examples, responsive to the receiving, generating an analytical model by generating an environment based on the location information, generating at least one list of vertices and materials indexed to the one or more model objects, and determining energy transmissions of the analytical model based on energy transmissions through surfaces of the one or more model objects.

Particular embodiments of the subject matter described in this specification can be implemented to realize one or more of the following advantages. Energy data may be determined and presented to a user throughout a design process. In some examples, such data may be presented in a step-wise manner to allow a user to step through iterations of the design and evaluate each iteration with respect to its energy transmissions. Additionally, or alternatively, a user may evaluate, at each iteration, various alternate geometries and/or materials that would affect the energy transmissions of such iteration. Users may appreciate and/or implement changes in his or her design model based on the above advantageous information. Such advantages improve building technologies by allowing designers to understand energy efficiency of various designs early in the design process and make changes accordingly. Additionally, the devices, systems, and methods provide such advantages to users through efficient processes that improve the analysis of computing devices through which the methods disclosed herein operate. For example, as will be apparent throughout this disclosure, energy analysis is completed on a plurality of transforms of designs at a plurality of different times, filtered by one or more constraints, and ranked to provide users the most accurate and relevant energy analysis to his or her design. Furthermore, analysis may be performed on incomplete designs (e.g., unconnected model objects, open geometries without volumes, etc.). In some examples, surface temperatures of external surfaces are calculated assuming interior temperatures are maintained. In some examples, the devices, systems, and methods disclosed herein utilize surface directionality for distinguishing between interior or exterior rather than additional geometry, zones, or volumes to represent an interior.

### BRIEF DESCRIPTION OF THE DRAWINGS

FIG. 1 illustrates an example environment including a local instance and a remote server in communication via a network.

FIG. 2 illustrates an example hardware platform on which the various elements described herein can be implemented.

FIGS. 3-8 illustrate flow charts representing computer readable instructions that may be executed to implement the systems and methods described herein.

FIGS. 9A-9B illustrate example graphical user interfaces associated with the systems and methods described herein.

FIGS. 10A-10B illustrate graphical representations of unification of the vertices of the design model.

### DETAILED DESCRIPTION

In the following description of the various embodiments, reference is made to the accompanying drawings, which form a part hereof, and in which is shown by way of illustration, various embodiments of the disclosure that may be practiced. It is to be understood that other embodiments may be utilized.

Modern design processes often comprise user generation of design models representing structures in CAD environments. Design models often comprise one or more model objects (MO). Accordingly, as used herein, a design model is expressly defined to include at least one MO generated in a CAD environment by a user. As an example, a design model may be a computer-generated three-dimensional graphical model of a building (design model) comprising one or more walls (MOs) designed in a CAD environment. Model objects generally consist of at least two types of information, geometry information and layer attribute information. Geometry information constitutes a vector math description of the given form of the model object. The geometry information may comprise, without limitation, area data, normal data, and vertex data. For example, the geometric information may define a surface of a wall of the building, such as the façade.

Layer attributes provide users with a means to structure the model object in particular ways. Often layer attributes are used to associate model objects with material values. For example, a model object representing a window may be associated with the material layer attribute “glass.” Other types and variants of the types of material layer attributes may be available. Design processes that take place in CAD environments regularly involve the stepwise creation, deletion, alteration, and/or manipulation of model objects. Aspects of the present disclosure are directed to tools and techniques that integrate with or are imbedded in CAD environments.

In some examples, an energy model is created from profile information associated with a design model. The profile information may be a representation of the actual model objects within a design model. Location information can be assigned to the energy model. For example, location information can be a city identifier in which the building is to be built, information regarding an object that another object is within (e.g., a piston in an engine), etc. Climate information can be determined from the location information in order to create the energy model for the design model.

In some examples, various alternate options with varying levels of associated energy transmission are presented to a user. A search is performed based on the actual model objects within the design model, alternate geometries, alternate materials, and one or more constraints. A portion of the search results are provided to the user to allow the user to evaluate his or her design model in comparison with the alternate options. For example, a design model of a building may comprise four glass walls, and the search, as disclosed further herein, may suggest that making one or more of the glass walls into brick walls would be more energy efficient.

Aspects of the present disclosure pertain to creating an energy chronology of the design model. The energy chronology may include a navigable representation of energy transmissions for multiple versions of the design model produced during the stepwise development of the design model. Aspects of creating an energy chronology can include monitoring the stepwise development of a design model, generating an energy model of the design, and recording outputs of the energy model in the energy chronology.

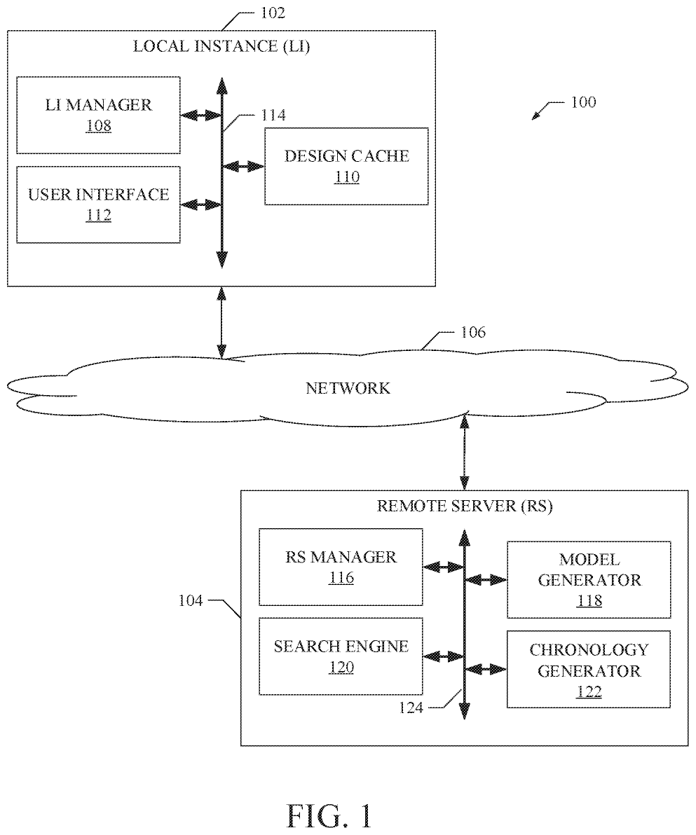

In examples disclosed herein, a system 100 may be utilized to analyze model objects created by a user in CAD environments. As described herein, a design model includes at least one MO generated in a CAD environment by a user. In some examples, a local instance (LI) 102 is associated with a user console such as, for example, a desktop computer, cloud computer, etc. For example, the local instance 102 may a plug-in for CAD software (e.g., Rhinoceros, AutoCAD, Revit, SketchUp, etc.) executing in connection with the user console. The local instance 102 may communicate with a remote server (RS) 104 and/or other elements via a network 106 (e.g., the Internet). The local instance 102 may comprise at least a LI manager 108, a design cache 110, and a user interface 112. While the local instance 102 is illustrated as comprising the LI manager 108, a design cache 110, and a user interface 112, the local instance 102 may comprise additional elements not shown in FIG. 1. The LI manager 108, design cache 110, and user interface 112 may communicate with each other, the network 106, and/or other elements via a bus 114.

The LI manager 108 may manage the design cache 110 and user interface 112 in connection with user manipulation of the user console. For example, as a user creates, deletes, or otherwise manipulates model objects within a CAD environment, the LI manager 108 (as further described herein) may at least monitor, analyze, store, and/or report such user manipulations. The LI manager 108 may associate each MO of a design model with a design profile in the design cache 110 using unique identifiers for identification.

The LI manager 108 may compare information corresponding to a design model within a CAD environment with information corresponding to design profile(s) stored within the design cache 110 and associated with the design model. For example, when a MO is created, deleted, altered, or otherwise manipulated, the LI manager 108 may store data corresponding to the MO and/or the change in the MO (e.g., the difference between a MO at time 1 and a MO at time 2 after a manipulation) in the design cache 110. While the user generated MO may be represented as a three-dimensional graphic in the CAD environment, the LI manager 108 may store data corresponding to a mathematical representation of the three-dimensional graphic such as vector information, geometry information, layer attribute information, identifying information, etc. For example, the LI manager 108 may identify and store area, vertex, normal, and material data for a MO. The LI manager 108 may store such information in the design cache 110 as a design profile for the MO. The LI manager 108 may update the design profile as the MO is manipulated by a user.

The design cache 110 may comprise a plurality of design profiles for a plurality of MOs. The example design profiles may mathematically describe the model objects of a design model such that graphical representations of the model objects could be recreated based on the design profiles. The design profiles may include additional information such as location, environmental conditions associated with a MO, etc. In some examples, all model objects in the CAD environment may have corresponding design profiles associated with unique identifiers. When storing design profiles in the design cache 110, the LI manager 108 may determine which model objects are the same, which model objects have been altered, and which model objects are new. Thus, in some examples, the design cache 110 stores different versions of model objects including a first version at a first time before a user alteration and a second version at a second time after the user alteration. The LI manager 108 may determine the amount or degree of which one or more model objects have been manipulated and/or altered. The LI manager 108 may compare the determined amount or degree of manipulation to a threshold. If the LI manager 108 determines that the determined amount or degree of manipulation satisfies (e.g., is greater than or equal to) the threshold, the LI manager 108 may transmit the design profile corresponding to the altered MO to the remote server 104.

The example user interface 112 provides a portal between a user and the devices, systems and methods described herein. For example, the user interface 112 presents, to the user, data corresponding to the energy analysis as further described herein. Additionally, the user interface 112 allows a user to select and/or modify constraints to be used during the search, browse through search results, manually request energy analysis of a design model at any given time, adjust user preferences, edit location information, etc.

The remote server 104 may comprise a RS manager 116, a model generator 118, a search engine 120, and a chronology generator 122. The remote server 104 may communicate with the local instance 102 and/or other elements via the network 106. While the remote server 104 is illustrated as comprising the RS manager 116, the model generator 118, the search engine 120, and the chronology generator 122, the remote server 104 may comprise additional elements not shown in FIG. 1. The RS manager 116, the model generator 118, the search engine 120, and the chronology generator 122 may communicate with each other, the network 106, and/or other elements via a wired or wireless connection, illustrated as a bus 124 in FIG. 1.

The example RS manager 116 may receive design profiles from the local instance 102 in response to the threshold being satisfied and/or in response to a manual request from a user through the user interface 112. The RS manager 116 may package outputs of the model generator 118, search engine 120, and/or chronology generator 122. The RS manager 116 may send the packaged outputs to the local instance 102 to be displayed via the user interface 112. Example packages generated by the RS manager 116 include an energy profile, which may include a line graph for a design model plotting an output of the example model generator 118 over time (e.g., across twelve months of a year, a minute, or any other appropriate timeframe), line graphs for variants of the design model determined by the search engine 120, a bar graph energy chronology for iterations of the design model based on the outputs of the chronology generator, textual information regarding the design model, the design profile of the design model, a graphical representation of the design model, indexed data associated with the design model, etc.

The example model generator 118 generates a mathematical model based on received design profiles from the local instance 102. The model generator 118 analyzes the generated mathematical model to determine energy transmissions of the design model. For example, the model generator 118 may apply one or more mathematical equations to the generated mathematical model as will be further described herein. As described below, the model generator 118 may additionally generate a plurality of alternate mathematical models based on the received design profiles and a plurality of alternate geometries and/or material attributes determined by the example search engine 120.

The example search engine 120 manipulates the input data used to generate the mathematical model by providing users various alternate MO attributes to use in connection with or instead of the MO attributes used to create the design. For example, while an initial mathematical model may be generated by the example model generator 118 based on the design model, the example search engine 120 may identify a plurality of alternate geometries and/or material attributes that could potentially be used in the design model. Such alternate geometries and/or material attributes may be subject to extrinsic constraints (e.g., user defined constraints and preferences) and intrinsic constraints (e.g., defined by physics). The example search engine 120 may provide such plurality of alternate geometries and/or material attributes to the model generator 118 for generation of a plurality of alternate mathematical models based on the design profiles and the plurality of alternate geometries and/or material attributes.

The example chronology generator 122 generates a history of the results of the analysis by the model generator 118. Each “step” of a design model may be stored chronologically. As described herein, a “step” is determined when a variance in the design model satisfies a threshold. The generated chronology may be presented to a user through the user interface 112. Each “step” may be selected by user through the user interface 112 to navigate through the chronology of the design model. The chronology may be associated with the energy profiles and design model such that as a user navigates through the “steps” of the design model and energy profile is updated to reflect the selected “step.”

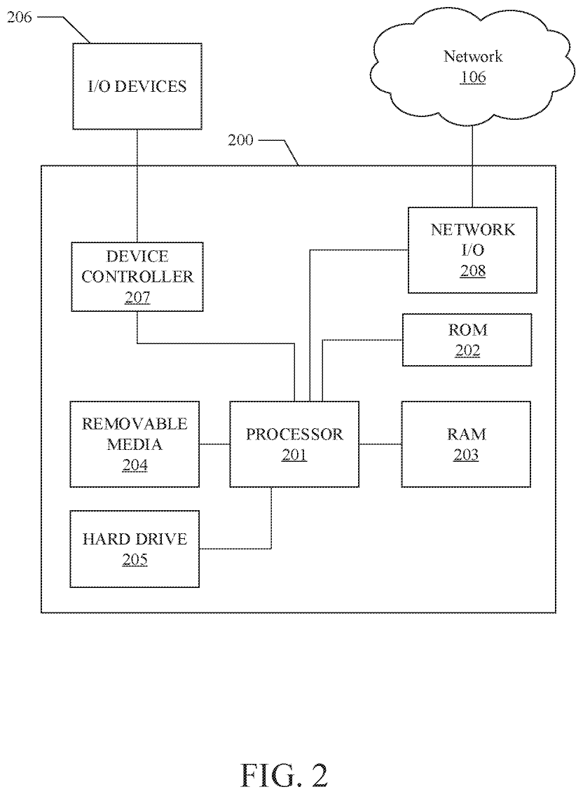

As disclosed herein, the local instance 102, the remote server 104, and/or other computing devices described herein may be implemented via a hardware platform such as, for example, the computing device 200 illustrated in FIG. 2. In some examples, the computing device 200 may implement the elements of the local instance 102 and the remote server 104, such that all elements are incorporated into a single device. Some elements described with reference to the computing device 200 may be alternately implemented in software. The computing device 200 may include one or more processors 201, which may execute instructions of a computer program to perform any of the features described herein. The instructions may be stored in any type of tangible computer-readable medium or memory, to configure the operation of the processor 201. As used herein, the term tangible computer-readable storage medium is expressly defined to include storage devices or storage discs and to exclude transmission media and propagating signals. For example, instructions may be stored in a read-only memory (ROM) 202, random access memory (RAM) 203, removable media 204, such as a Universal Serial Bus (USB) drive, compact disk (CD) or digital versatile disk (DVD), floppy disk drive, or any other desired electronic storage medium. Instructions may also be stored in an attached (or internal) hard drive 205. The computing device 200 may include one or more input/output devices 206, such as a display, touch screen, keyboard, mouse, microphone, software user interface, etc. The computing device 200 may include one or more device controllers 207 such as a video processor, keyboard controller, etc. The computing device 200 may also include one or more network interfaces 208, such as input/output circuits (such as a network card) to communicate with a network such as example network 106. The network interface 208 may be a wired interface, wireless interface, or a combination thereof.

One or more of the elements described above may be removed, rearranged, or supplemented without departing from the scope of the present disclosure.

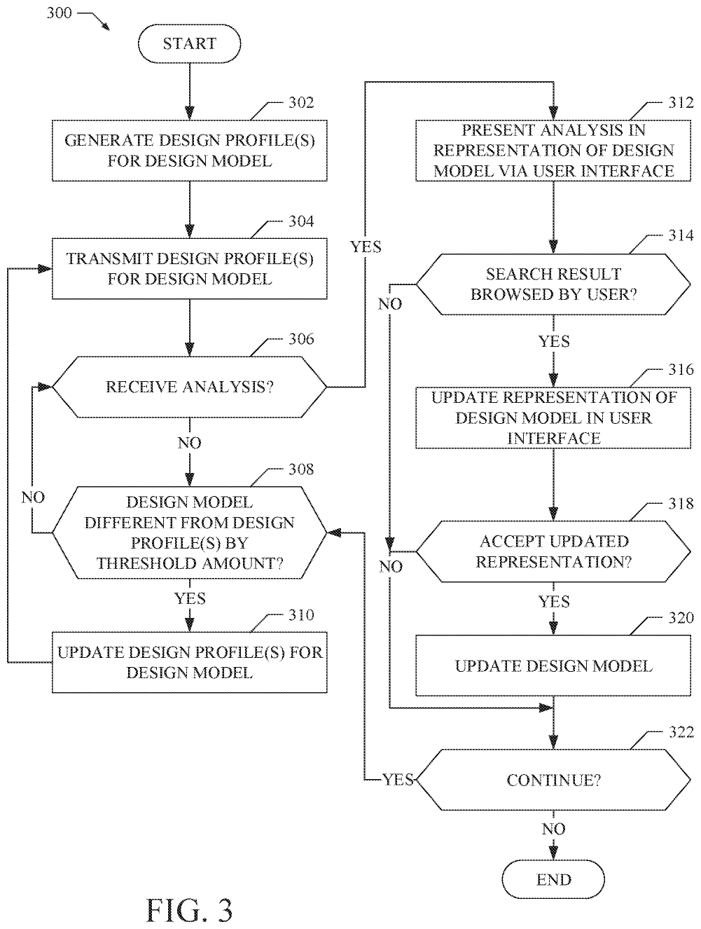

FIG. 3 illustrates a flow chart representative of machine readable instructions that, when executed, may cause a computing device to implement a process 300. The example process 300 may begin at block 302. At block 302, the LI manager 108 may generate one or more design profiles for the design model. At block 304, the LI manager 108 may transmit the one or more design profiles to RS manager 116. In some examples, the RS manager 116 forwards the one or more design profiles to the model generator 118. In some examples, the model generator 118 may be located at the remote server 104. In some examples, the model generator 118 may be local to LI manager 108. The one or more design profiles for the design model generated by the LI manager 108 may be stored in the design cache 110. Thereafter, the example LI manager 108 may determine whether analysis based on the transmitted design profiles is received (block 306). In some examples, the received analysis includes an energy profile, as disclosed herein. In some examples, the analysis may be received from the RS manager 116 of the remote server 104. In some examples, the RS manager 116 may be local to the LI manager 108 and the analysis may be received from a local connection (e.g., bus 114). If analysis has not been received (block 306: NO), control proceeds to block 308.

At block 308, the LI manager 108 determines whether the design model is different from the design profiles stored in the design cache 110 by a threshold amount. If the design model is not different from the design profiles stored in the design cache 110 by the threshold amount (block 308: NO), control returns to block 306. If the design model is different from the design profiles stored in the design cache 110 by the threshold amount (block 308: YES), control proceeds to block 310. At block 310, the LI manager 108 updates the design profiles stored in the design cache 110 with design profiles for the modified design model. Thereafter, control returns to block 304.

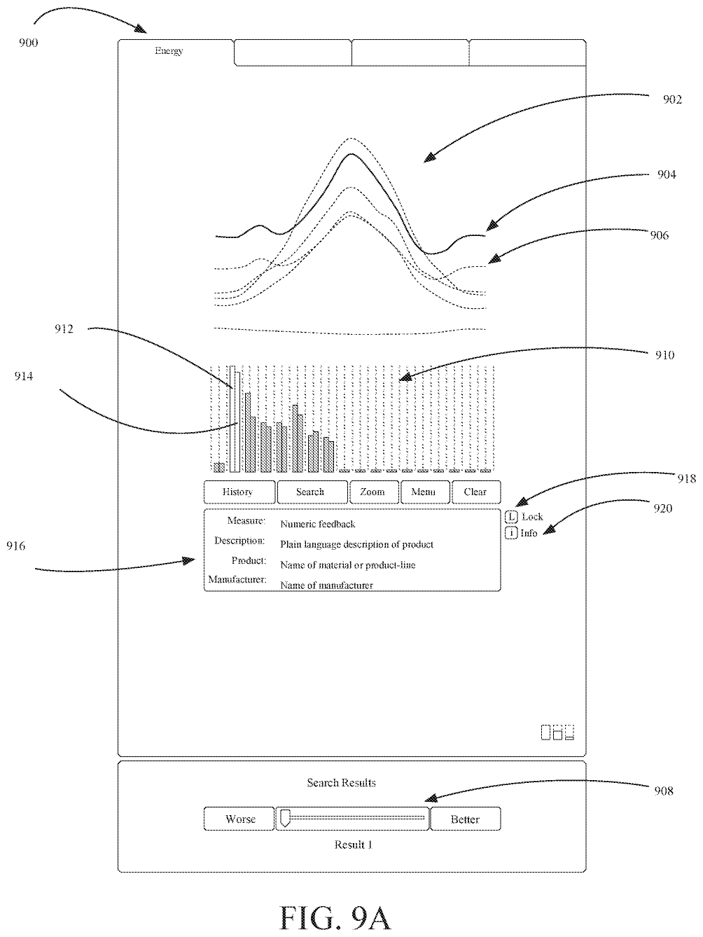

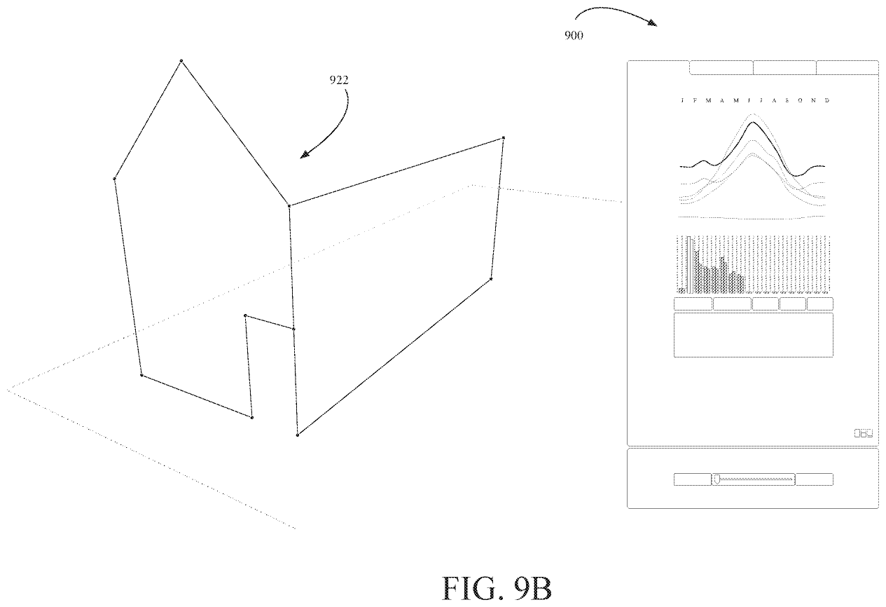

If the example LI manager 108 has received analysis (block 306: YES), control proceeds to block 312. At block 312, the received analysis is presented to a user of the user console via the user interface 112. The analysis may be presented in one or more graphs, text boxes, three-dimensional representations that may be navigable and/or selectable by a user. For example, the analysis may be presented as a line graph with varying values through a calendar year, a bar graph illustrating a chronology of analysis over many iterations of one or more MOs/the entire design model, a virtual three-dimensional representation illustrating the design model associated with the analysis, etc. Example representations of the user interface 112 are shown in FIGS. 9A-9B.

In some examples, the analysis may comprise one or more search results and data analysis in connection with the one or more search results in addition to the data analysis based on transmitted design profiles. For example, as described herein, alternate geometries and/or materials may be utilized in the analysis to provide alternate design model transforms that may improve the design model of a user. Such search results may be presented in association with the analysis packaged in the one or more graphs, text boxes, three-dimensional representations and may include respective energy profiles. In some examples, as the packaged search results are browsed by a user, the graphical representations of the analysis associated with a selected MO and/or the entire design model may be updated to reflect the materials and/or geometry of the browsed packaged search result.

At block 314, the example LI manager 108 determines whether a user has browsed the presented search results. If the example LI manager 108 determines that a user has browsed the packaged search results (block 314: YES), control proceeds to block 316. At block 316, the LI manager 108 updates the graphical representation of the design model via the user interface 112 to reflect the geometry and/or materials associated with the browsed search result. At block 318, the LI manager 108 may determine whether a user has accepted the browsed search result such that it should be incorporated into the actual design model. For example, as illustrated in FIG. 9A, a user may accept a browsed search result by selecting an option 918 on the user interface 112. If the LI manager 108 determines that a user has accepted the browsed search result (block 318: YES), control proceeds to block 320. At block 320, the LI manager 108 updates the design model with the accepted browsed search result. In some examples, the design model may be updated based on the whole or portions of whole accepted browsed search result. For example, single model objects may be updated, the entire design model may be updated, etc. In some examples, the design model is directly updated with the geometry and/or material associated with the accepted browsed search result. In some examples, the geometry and/or material associated with the accepted browsed search result are attached to the design model and/or design profile as a preference or attribute. After block 320, if the example LI manager 108 determines that a user has not browsed the presented results (block 314: NO), or if the LI manager 108 determines that a user has not accepted the browsed search result (block 318: NO), control proceeds to block 322.

While an exit routine may occur at any time, an example exit routine is illustrated as block 322 in FIG. 3. At block 322, the example LI manager 108 determines whether to continue analyzing new design profiles. For example, the LI manager 108 may determine whether there are any errors, if there are enough resources (e.g., power, processors, memory, etc.), or other known reasons to exit process 300. If the example LI manager 108 determines to continue (block 322: YES), control returns to block 308. Otherwise (block 322: NO), process 300 ceases operation.

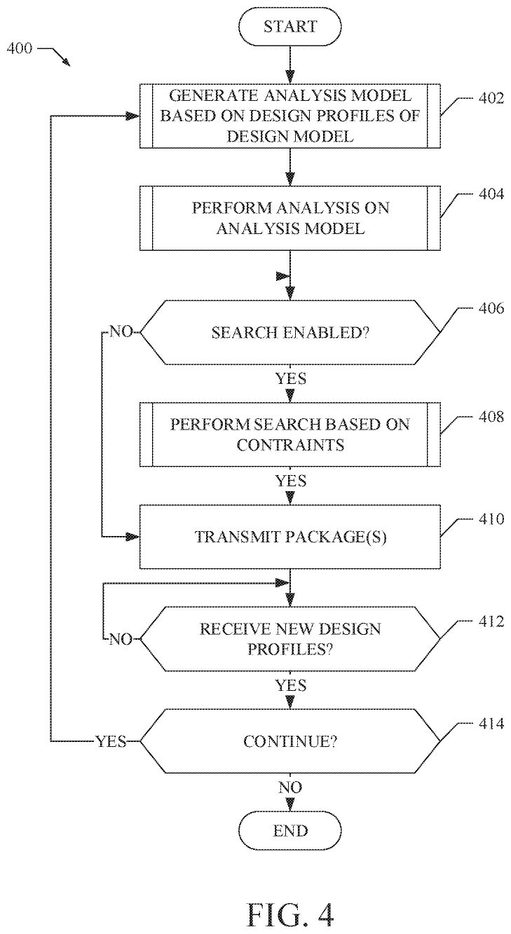

FIG. 4 illustrates a flow chart representative of machine readable instructions that, when executed, may cause a computing device to implement a process 400. The example process 400 may begin at block 402. Initially, the example RS manager 116 may receive, from the LI manager 108, design profiles corresponding to a design model generated at a user console. As described above, the design model may include a single MO created by a user or multiple model objects created by a user over time or loaded from a saved file. The example model generator 118 may generate an analysis model based on the received design profiles of the model objects in the design model (block 402). The generated analysis model may be a mathematical representation of the information in the design profiles. The example model generator 118 may perform data analysis on the generated analysis model (block 404). In some examples, the data analysis may be, without limitation, analysis of the energy transmissions through the surfaces of the model objects that collectively form the design model.

While a search may be enabled at any time during the process 400, an example search check is illustrated as block 406 of FIG. 4. The example RS manager 116 may determine whether searching has been enabled by a user (block 406). For example, geometric and material constraints may be used to determine whether a search is enabled and to what extent a search is enabled. For example, if geometric and material constraints are set to “locked,” a search is disabled. Likewise, if geometric and material constraints are set to “unlocked” the broadest search is enabled. The following are examples of constraints that may be utilized herein.

For geometries:
Locked—This constraint may prevent a geometry search for identified model objects. For example, a user may not wish to search for alternate geometry for his or her design model.
Low—This constraint may allow a low degree of geometric search for identified model objects. For example, a user may wish to search for geometry similar or close to his or her design model.
Medium—This constraint may allow a medium degree of geometric search for identified model objects. For example, a user may wish to search for various alternate geometry without significant departure from his or her design model.
Unlocked—This constraint may allow a high degree of geometric search for identified model objects limited only by implicit constraints (e.g., constraints defined by physics). For example, a user may wish to search for all alternate geometries.

For materials:
Locked—This constraint may prevent a material search for identified model objects.
Sub-Type 1—This constraint may enable a product-line based material search. For example, if a model object is assigned to the category of glass, applying a sub-type 1 constraint may limit material searches for the selected object to a group of related products sold by a particular manufacture.
Sub-Type 2—This constraint may enable a brand, manufacturer, or supplier based material search. For example, if a model object is assigned to the category of glass, applying a sub-type 2 constraint may limit material searches for the selected object to the particular brands, manufacturers, or suppliers of glass.
Material Type—This constraint may enable a type based material search for the selected model object. For example, if a model object is assigned to the category of glass, applying a type material constraint may limit material searches for the selected object to the category of glass.
Palette—This constraint may enable a palette based material search for the selected model object. For example, if a model object is assigned to the category of glass, but the larger design has glass, metal and wood materials in use, applying a palette material constraint may limit material searches for the selected object to glass, metal and wood materials.
Unlocked—This value, when assigned to a model object, enables any material to be used during a material search for the selected model object. All library materials may be searched when creating a solution for the selected model object.

There may be any number of constraints between “locked” and “unlocked” for both materials and geometry such that various searching spaces may be created, as further disclosed herein.

If the example RS manager 116 determines that searching has been enabled by a user (block 406: YES), control proceeds to block 408. At block 408, the example search engine 120 performs a search for alternate geometries and/or materials for the model objects in the design model based on one or more constraints, as described above. Thereafter, or if the example RS manager 116 determines at block 406 that searching has not been enabled by a user (block 406: NO), control proceeds to block 410. At block 410, the example RS manager 116 may package the results of the data analysis and/or search and transmit the package(s) to the LI manager 108. In some examples, the LI manager 108 forwards the package(s) to the user interface 112 for presentation to the user.

While design profiles may change at any time, an example check is illustrated as block 412 of FIG. 4. At block 412, the example RS manager 116 determines whether new design profiles have been received. For example, the example LI manager 108 may transmit new design profiles if the example LI manager 108 determines that the design profiles in the design cache 110 have changed by a threshold amount (block 308, FIG. 3). If the example RS manager 116 determines that new design profiles have not been received (block 412: NO), control returns to block 412. If the example RS manager 116 determines that new design profiles have been received (block 412: YES), control proceeds to block 414.

While an exit routine may occur at any time, an example exit routine is illustrated as block 414 in FIG. 4. At block 414, the example RS manager 116 determines whether to continue processing new design profiles. For example, the RS manager 116 may determine whether there are any errors, if there are enough resources (e.g., power, processors, memory, etc.), or other known reasons to exit process 400. If the example RS manager 116 determines to continue (block 414: YES), control returns to block 402. Otherwise (block 414: NO), process 400 ceases operation.

While FIG. 3 and FIG. 4 are illustrated as separate flow diagrams, one of ordinary skill in the art would understand that the processes of FIG. 3 and FIG. 4 may operate on a single device or a plurality of devices and may operate serially or in parallel without departing from the scope of the present invention.

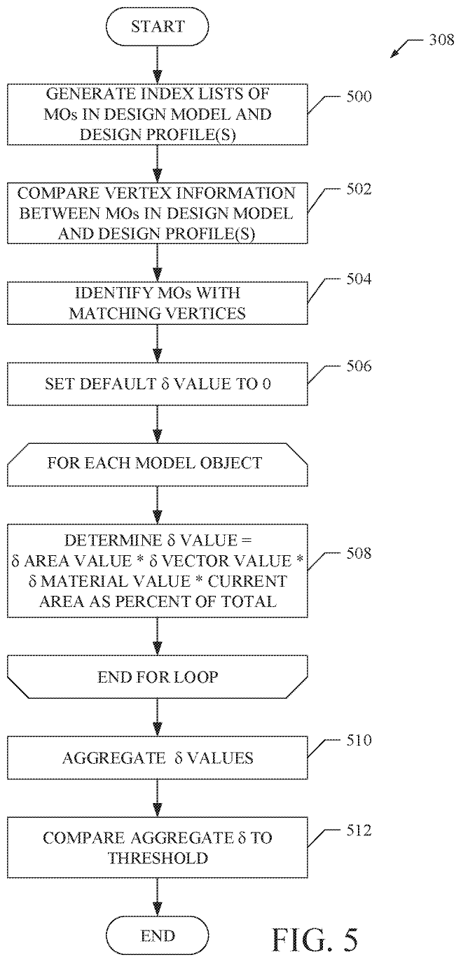

FIG. 5 illustrates a flow chart representative of machine readable instructions that, when executed, may cause a computing device to implement block 308 of FIG. 3 to determine whether a design model differs from corresponding design profiles by a threshold amount. The example implementation of block 308 to perform the above described process may begin at block 500. In some examples, to determine whether a design model differs from corresponding design profiles by a threshold amount, Boolean arrays are used. In the examples disclosed below, to determine whether a design model differs from corresponding design profiles by a threshold amount, indexing methodologies are used.

At block 500, the example LI manager 108 may generate a first index list for model objects associated with the design model and a second index list for representations of model objects associated with the design profile(s) within the design cache 110. To determine which model object within the first list corresponds with an associated model object within the second list, the example LI manager 108 may compare the vertex information associated with the model objects within the design model with vertex information associated with the model objects within the design cache 110 (block 502).

At block 504, the example LI manager 108 may identify which model objects in the design model have vertices that match with model objects within the design cache 110 to find corresponding model objects between the lists. For example, the first index list associated with the design model may include a first model object and a second model object. The first model object may be building façade and the second model object may be a building roof. The second index list associated with the design profile may include a representation of a model object corresponding to the building façade. To determine which of the first model object or the second model object corresponds to the representation of the model object in the design profile, the LI manager 108 may compare the vertices of the representation of the model object in the design profile with the vertices of the first and second model objects and may identify that the representation of the model object in the design profile (e.g., the building façade associated with the design profile) corresponds to the first model object (e.g., the building façade associated with the design model), because the vertices match. Any additional non-matching model objects may be determined to be new. While identifying matching vertices is helpful to determine which model object associated with the design model corresponds to which representation of a model object associated with the design profile, other information, such as vector and material information, may differ between a model object associated with the design model and a representation of a model object associated with the design profile. Therefore, additional qualities such as area, vector, material may be analyzed to quantify design changes.

In order to determine a numerical value corresponding to any difference between the model objects associated with the design model and representations of model objects associated with the design profiles, the example LI manager 108 may first set a default change (δ) value to zero for each model object. Thereafter, the LI manager 108 determines a δ value for each MO, according to the following equations:

δ value=(δ area value)*(δ vector value)*(δ material value)*(current area %) Equation 1

For MOs with matching vertices, the LI manager 108 determines the δ area value, δ vector value, δ material value, and the current area % based on Equations 2-5 set forth below:

$$\begin{matrix} Equation 2 \\ δ area value = \frac{( design model MO area - design profile MO area )}{design profile MO area} * 100 \\ Equation 3 \\ δ material value = \\ \{ \begin{matrix}1 , if design model MO material = design profile MO material \\ a constant not equal to 0 ( e . g . , 2 ) , else\end{matrix} \\ Equation 4 \\ δ vector value = \\ \{ \begin{matrix}1 , if design model MO normal = design profile MO normal \\ a constant not equal to 0 ( e . g . , 2 ) , else\end{matrix} \\ Equation 5 \\ current area \% = \frac{design model MO area}{\sum design profile area}\end{matrix}$$

For new MOs, the LI manager 108 determines the δ area value, δ vector value, δ material value, and the current area % based on Equations 6-8 set forth below and Equation 5:

δ area value=a constant not equal to 0 (e.g., 2) Equation 6

δ vector value=a constant not equal to 0 (e.g., 2) Equation 7

δ material value=a constant not equal to 0 (e.g., 1) Equation 8

At block 510, the example LI manager 108 aggregates or otherwise sums together the δ values to produce an aggregate δ value. At block 512, the example LI manager 108 compares the aggregate δ value to a threshold. The example threshold may be a range variable used to describe when a degree of change is significant enough for the design cache 110 to be updated with the information corresponding to the design model. The example threshold may be set to avoid updating every single modification of the design model, which may be deemed tedious. However, the threshold may be set low to update the design cache 110 with every modification that occurs within the CAD environment. Multiple alterations, the addition of multiple objects to the design model, or the removal of multiple objects from the design model may be examples wherein the aggregate δ value satisfies the threshold. After block 512, the example implementation of block 308 may cease operation.

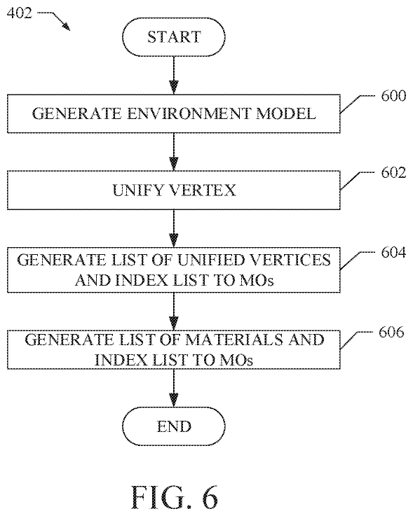

FIG. 6 illustrates a flow chart representative of machine readable instructions that, when executed, may cause a computing device to implement block 402 of FIG. 4 to generate an analysis model. Initially, the model generator 118 may receive location, geometry, and/or material information associated with design profiles from the design cache 110. The received location, geometry, and/or material information may include a list of vertices and additional information that may allow the model generator 118 to reassemble the design model. In some examples, the received geometry may be triangulated and may contain redundant vertices. In some examples, the triangulation may create redundant material information, geometric constraints, and/or material constraints.

At block 600, the example model generator 118 generates an environment model based on the received location information. The environment model may include environment data corresponding to the location. In some examples, the environment data may correspond to nature (e.g., seasons, length of day, sun angles, temperatures, weather conditions, etc.). In some examples, the environment data may correspond to any conditions in areas around structures (e.g., the conditions surrounding a piston within an engine).

At block 602, the model generator 118 unifies the vertexes of the design model for the analysis model based on the received geometry information to reduce redundancy. In some examples, the vertices of different model objects that share a same object space may be unified together as one. For example, the corners of two model objects that share an edge may be unified together. In some examples, edges of model objects do not perfectly align and, thus, do not have matching vertices. In order to unify the vertices of such edges, the model generator 118 forces the two model objects to have matching vertices. For example, if two model objects share/touch or are to share/touch a coincident edge or point, the model generator 118 may add vertex information to a model object of the analysis model to make the two model objects have matching vertices, such as shown below in the following examples:

### EXAMPLE 1

As shown below, an edge of shape A has two end points that match the end points of the coincident edge of shape B. Shape B has an additional point lying between its two end points.

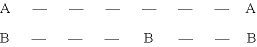

The model generator 118 may add a vertex between the two end points of shape A, as shown below, such that the vertices of shape A match the vertices of shape B.

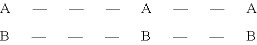

### EXAMPLE 2

As shown below, an edge of shape A has one end point beyond the edge of shape B and one end point between the end points of shape B. An edge of shape B has one end point between the end points of shape A and one end point beyond the edge of shape A.

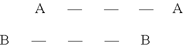

The model generator 118 may add a vertex between the two end points of shape A and add a vertex between the two end points of shape B, as shown below, such that the vertices of shape A and shape B match.

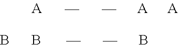

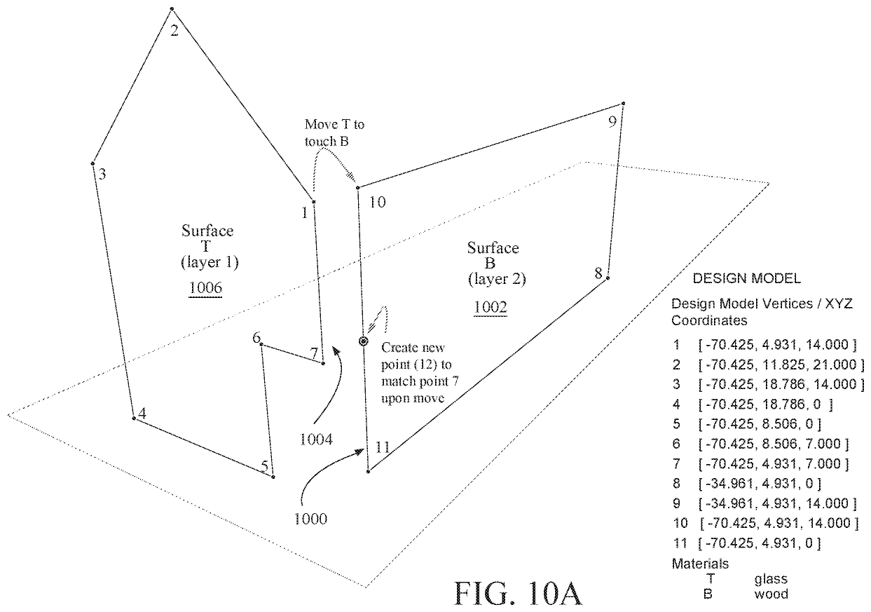

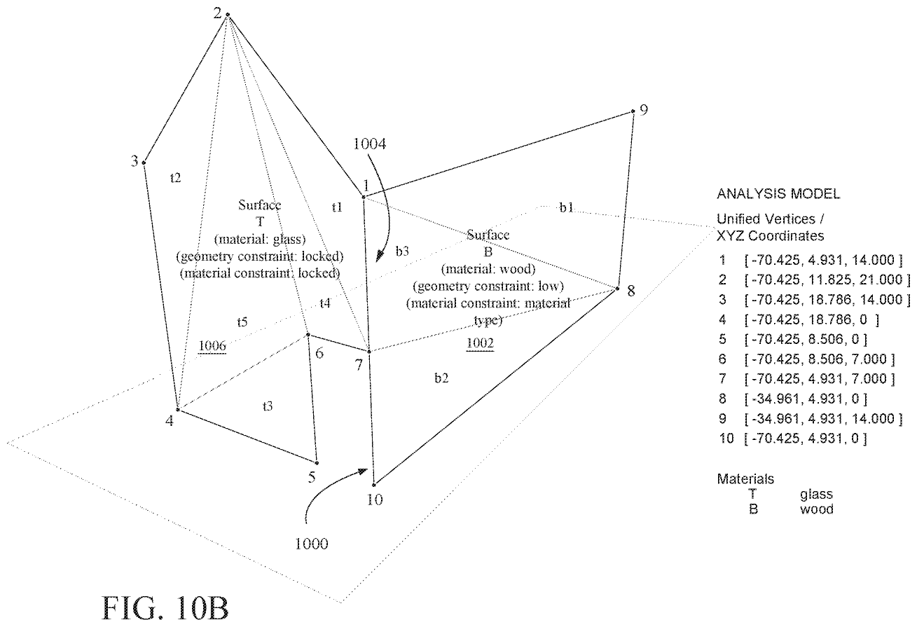

FIGS. 10A-10B graphically illustrate vertex unification. In FIG. 10A, a first edge 1000 of surface B 1002 may be defined by vertex 10 and vertex 11. Similarly, a second edge 1004 of surface T 1006 may be defined by vertex 1 and vertex 7. In some examples, the first edge 1000 may touch the second edge 1004 (e.g., as a result of distance unification as further described herein). While vertex 1 of surface T 1006 may match with vertex 10 of surface B 1002, surface B 1002 would not have a vertex corresponding to vertex 7 of surface T 1006. As shown in FIG. 10A, the model generator 118 may create a vertex 12 of surface B 1002 to correspond with vertex 7 of surface T 1006. In examples wherein the first edge 1000 is to touch the second edge 1004, as illustrated in FIG. 10B, vertex 1 and vertex 10 may be consolidated into vertex 1 and vertex 7 and vertex 12 may be consolidated into vertex 7.

At block 604, the example model generator 118 may generate a list of the unified vertices associated with the design model and may index the list to the respective model objects. For example, the model generator 118 may cross-reference the vertices list with an ordered list of model objects to produce an indexed listing of which vertices belong to which model object.

At block 606, the example model generator 118 may generate a list of materials associated with the design model and may index the list to the respective model objects. For example, the model generator 118 may cross-reference the materials list with an ordered list of model objects to produce an indexed listing of which materials belong to which model object.

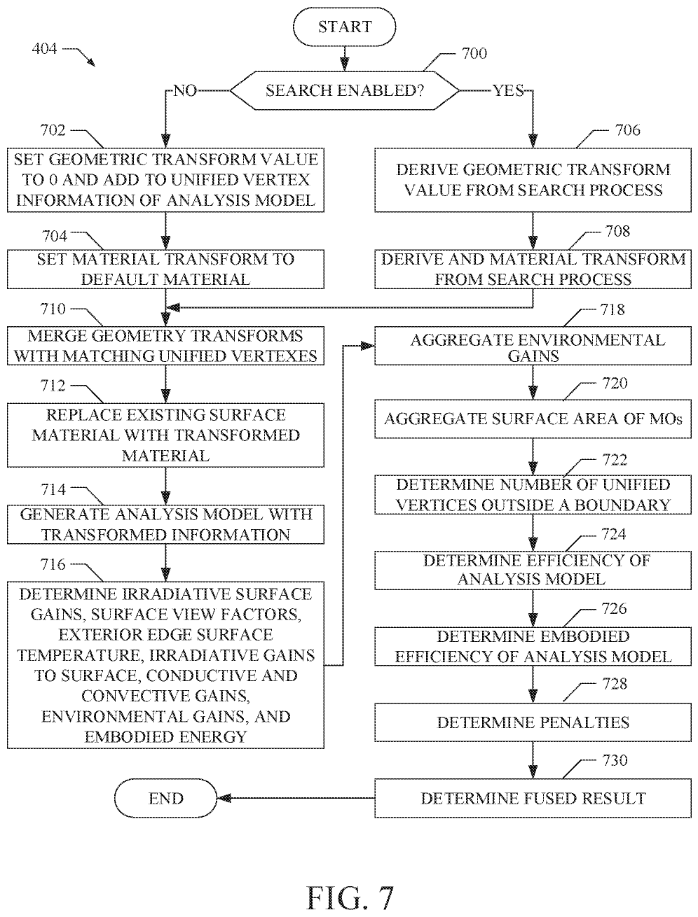

FIG. 7 illustrates a flow chart representative of machine readable instructions that, when executed, may cause a computing device to implement block 404 of FIG. 4 to analyze the analysis model. In examples disclosed herein, the analysis model reflects the actual model objects in a design model of a user. Accordingly, analysis of the analysis model corresponds to analysis of the design model.

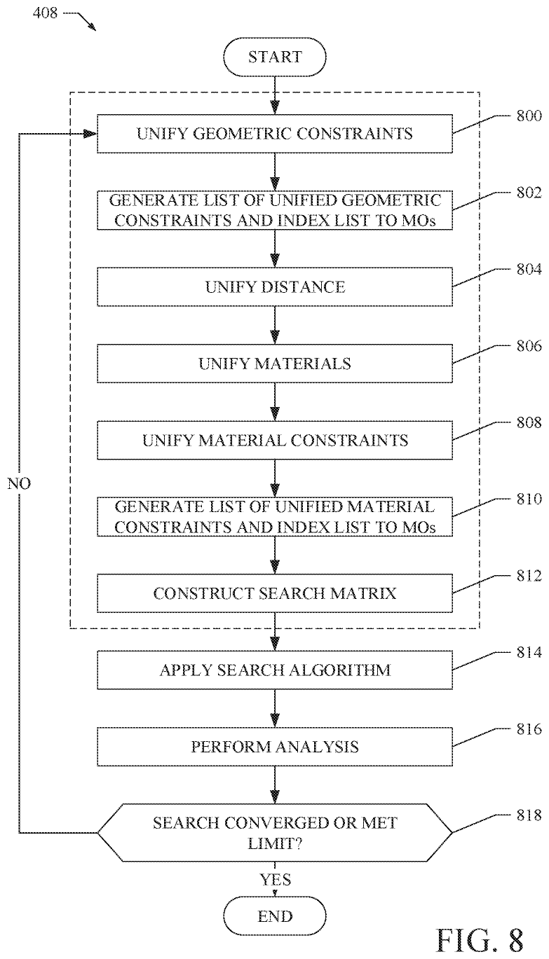

As described herein, analysis may include analyzing the energy transmissions through surfaces of the model objects represented in a design model. To determine such energy transmissions, the example implementation of block 404 begins at block 700. Because energy analysis may be applied to both the design model of a user and transforms determined by the search process (FIG. 8), the example RS manager 116 initially determines whether searching is enabled (block 700) (e.g., based on the constraints).

If searching is disabled (block 700: NO), control proceeds to block 702. At block 702, the example model generator 118 sets geometric transform values to zero and adds the geometric transform values to the unified vertex information in the analysis model. At block 704, the example model generator 118 sets the material transforms for each model object to a default material (e.g., a material selected by a user such as by selecting option 918 (FIG.9) in association with blocks 318-320 (FIG. 3), or some predetermined material).

If searching is enabled (block 700: YES), control proceeds to block 706. At block 706, the example model generator 118 derives geometric transform values from the search process (FIG. 8) and adds the geometric transform values to the unified vertex information in the analysis model. At block 708, the example model generator 118 sets material transforms for each model object based on indexed values derived from the search process (FIG. 8).

After block 704 or block 708, control proceeds to block 710. At block 710, the example model generator 118 merges the geometric transforms with matching unified vertexes to create transformed unified vertex information for use in the analysis process. For example, Equation 9 illustrates an example equation for such a merge:

transformed unified vertex (X Y Z)=vertex location of analysis model (x,y,z)+vertex transform from search (xt,yt,zt) Equation 9

Equation 9 corresponds to the three-dimensional spherical transform that a vertex varied based on a search result. The transform may be zero if there is no geometric transform from a search.

At block 712, the example model generator 118 replaces existing material associated with the analysis model with the transformed material determined via blocks 704, 708. At block 714, the model generator 118 may generate a transformed model (FIG. 6), with the transformed information determined at blocks 710, 712. In some examples, the transformed model generated at block 714 is the same as the previously generated analysis model as described in connection with FIG. 6. In some examples, the transformed model generated at block 714 varies based on the search process (FIG. 8). Based on the transformed model generated at block 714, the example model generator 118 may determine one or more energy transmission factors for each model object based on, at least, thermal air, air-film or fluid information of environment, irradiative information of environment (i.e. transfer sources, their directions and magnitudes, and environmental qualities due to black body and environmental factors surrounding the boundary), thermal and irradiative information for boundary base, which represents a physical element that touches the design in some way (i.e. transfer sources, their directions and magnitudes for a part mount, base or building site), thermal and irradiative information of designed surfaces (block 716). In some examples, determining the one or more energy transmission factors for each model object comprises determining energy transmission factors for corresponding surfaces and the associated assembly (e.g., a brick wall associated with insulation, membranes, air gaps, interior finishes, etc.). The example model generator 118 may receive such information from the design profiles. Alternately, the model generator 118 may query a database or third party sources for such information based on the location, geometry, and/or material information received from the design profiles.

The energy transmission factors may include, without limitation, irradiative surface gains, surface view factors, exterior edge surface temperature, irradiative gains to surface, conductive and convective gains, environmental gains, and embodied energy (block 716). Irradiative surface gains may correspond to irradiative gains of each designed surface. Surface view factors may correspond to view factors of a design relative to boundary base for each surface. For example, a building façade may be relative to the earth, an engine component may be relative to the engine block, etc. Exterior edge surface temperature may correspond to the surface temperature of a face given all conditions, for example a Sol-Air temperature of the designed surface. Irradiative gains to surface may correspond to energy (e.g., radiation) that arrives at a surface interior by passing through each designed surface. Conductive and convective gains may correspond to positive or negative temperature gains based on a known temperature of a design surface interior, a determined exterior surface temperature, and known designed surface qualities. Environmental gains may correspond to energy that arrives to a surface interior by passing through each designed surface via air through an exterior edge (i.e. due to material permeability). Embodied energy may correspond to energy of a material associated with a design profile based on its design qualities (e.g., the energy required to manufacture the object). Embodied energy may include one or more constant values corresponding to other materials associated with a material assembly of a design profile.

At block 718, the model generator 118 may aggregate the environmental gains. As described herein, energy calculations are determined based on an aggregating analysis of the surfaces of model objects. Based on the aggregate gains determined at block 718, the model generator 118 may determine the total energy consumed (e.g., total energy consumption) based on an absolute value of the summation of the irradiation, convection, conduction, and air transfers on an hourly basis. Because the energy transmissions are determined for each MO and aggregated, a design model need not be closed, solid, or contain a volume. As the values determined at block 716 are aggregated, directionality (expressed as a normal) may be taken into account. This aggregate may be a single total as well as an array or list of time dependent totals (e.g., the environmental gains incurred over a period of time for one or more periods of time). For example, the aggregate may be broken down by month, day, hour, minute, second, millisecond, etc.

At block 720, the model generator 118 may aggregate the surface areas of each model object within a design. At block 722, the model generator 118 determines the number of unified vertices that lie outside of a boundary (if a boundary is present). At block 724, the model generator 118 determines the efficiency of the analysis model based on Equation 10.

$$Efficiency = \frac{Total Energy Consumption}{Total Surface Area} \qquad Equation 10$$

At block 726, the model generator 118 determines the embodied efficiency of the analysis model based on Equation 11.

$$Embodied Efficiency = \frac{Total Embodied Energy}{Total Surface Area} \qquad Equation 11$$

At block 728, the model generator 118 determines one or more penalty factors. The penalty factors may be used to encourage more helpful results. For example, one method of increasing energy efficiency through a model object is to reduce the area of the model object. However, reducing the area of a façade of a building is likely an unhelpful transform of a design model. Accordingly, one penalty determined by the model generator 118 may be an area penalty, which may be a penalty to be applied if area conditions are violated. The area penalty may be determined based on Equation 12.

if area varies by a threshold amount: Area Penalty=|Area of analysis model−Area of transformed model|*scale factor Equation 12

The model generator 118 may determine a period penalty representing a penalty to be applied if discrete energy measurements across a defined time period are violated. The period penalty may be determined based on Equation 13.

Period Penalty=Σ(Energy period of transformed model−energy period of analysis model)*scale factor ∀ Energy Period of Analysis Model<Energy Period of Transformed Model Equation 13

The model generator 118 may determine a boundary penalty representing a penalty to be applied if geometric solutions violate the site boundary condition. The boundary penalty may be determined based on Equation 14.

Boundary Penalty=Σ(Vertices outside boundary)*scale factor Equation 14

At block 730, the model generator 118 determines a fused result by combining the above calculations, such as by aggregating the efficiency, the embodied efficiency, the area penalty, the period penalty, and the boundary penalty. In some examples, the model generator 118 may determine an output of the energy analysis according to Equation 15.

Analysis Output=Efficiency+Embodied Efficiency+Area Penalty+Period Penalty+Boundary Penalty Equation 15

Alternatively, the model generator 118 may determine the fused result by combining the above calculations, such as by aggregating the total energy consumption, the total embodied energy, the area penalty, the period penalty, and the boundary penalty. In some examples, the model generator 118 may determine an output of the energy analysis according to Equation 16.

Analysis Output=Total Energy Consumption+Total Embodied Energy+Area Penalty+Period Penalty+Boundary Penalty Equation 16

In some examples, the analysis output corresponding to energy units such as, for example, Joules, Kilojoules, Kilowatt-hours, etc.

In some examples, the model generator 118 performs additional analysis based on Equation 16. The model generator 118 may apply one or more conversion factors may be applied to provide different information. For example, the model generator 118 may output an annual expected cost as a result of the energy analysis by multiplying a cost per energy unit to the output of Equation 16. Similarly, the model generator 118 may determine material costs to achieve the result of the energy analysis. Of course, additional valuable information can be determined based on the present disclosure without significant departure. After block 730, the example implementation of block 404 ceases operation.

FIG. 8 illustrates a flow chart representative of machine readable instructions that, when executed, may cause a computing device to implement block 408 of FIG. 4 to perform a search for alternate geometries and/or materials. As a search may be performed with respect to an analysis model, the data generated in connection with the description of FIG. 6 may be utilized by the search engine 120 during the search process.

As described above, one or more constraints define if a search is to be performed and the extent of such a search. In some examples, users define the constraints as preferences. For example, a user may wish to search for alternate geometries for his or her design model, but not alternate materials. A user may wish to search for alternate geometries and alternate materials for a single model object, but not all model objects within a design model. In some examples, such constraints may be selectable by a user through the user interface 112 as buttons, sliders, etc. As described above, example constraints may include locked, low, medium, and unlocked for geometries and may include locked, material type, sub-type 1, sub-type 2, palette, or unlocked for materials.

At block 800, the search engine 120 may begin the search process by unifying geometric constraints. For example, for each vertex in the design, the search engine 120 may apply the user selected geometric constraint (e.g., locked, low, medium, unlocked, etc.). As user selected constraints may be applied at a model object level, each vertex in a model object may be associated with the selected constraint. However, when one or more model objects share vertices (e.g., shape A and shape B share at least one vertex) and have different user selected constraints (e.g., shape A is assigned a geometric constraint value of “Low” and shape B is assigned a geometric constraint value of “Medium”), the search engine 120 selects the lowest of the geometric constraints. Alternatively, the highest of the geometric constraints or a default constraint defined by a user preference may be selected by the search engine 120. The search engine 120 applies a numerical factor corresponding with the selected geometric constraint. For example, a “locked” geometric constraint may be defined as a numerical factor of 0.0, a “low” geometric constraint may be defined as a numerical factor of 0.33, a “medium” geometric constraint may be defined as a numerical factor of 0.66, and an “unlocked” geometric constraint may be defined as a numerical factor of 1. Of course, any number of constraints with any numerical factor may be utilized without departing form the scope of the present disclosure.

At block 802, the search engine 120 may generate a list of the unified geometric constraints and index the list to respective vertices, that are assembled into surfaces through a second indexing list. The example geometric constraints may be used to limit the distance in which a vertex of a model object may vary during the search process (e.g., 0%, 33%, 66%, or 100% of a maximum distance). At block 804, the search engine 120 may unify the distance limit by creating a list of the distances between a vertex and all other vertices found in the analysis model and determining the minimum distance for each vertex. For example, if a model object consists of four vertices, then four sets of three values may result from measuring the distance between each vertex: (50, 20, 10), (50, 32, 2), (20, 32, 84), (10, 2, 84). In such an example, the minimum distances are (10, 2, 20, 2).

The example search engine 120 may determine ranges of distances that each vertex may vary. The search engine 120 may multiply the unified distance determined in block 804 (e.g., 10, 2, 20, 2) by the numeric factor (e.g., 0, 0.33, 0.66, or 1) determined in block 800. The search engine 120 may use this product as the maximum distance that a vertex may vary during a search and may use zero as the minimum distance that the vertex may vary. In some examples, the range between the minimum distance and the maximum distance may be broken down into any number of distance intervals. A distance interval may be determined by dividing the maximum distance by the number of distance intervals. For example, if one wanted ten distance intervals in the range between the minimum distance and the maximum distance, the maximum distance would be divided by ten, with the result being the distance interval. As described herein, a vertex may vary between the range described above according to the above described distance intervals.

The search engine 120 may also determine an elevation transform range for each vertex where the highest and lowest elevation values in the range equal the respective values to be used in a search and the search engine 120 may also determine an azimuth transform range for each vertex where the highest and lowest azimuth values in the range equal the respective values to be used in a search. In some examples, the range in which a vertex may vary corresponds to a three-dimensional spherical mapping, such that a vertex may vary in three-dimensions bounded by the elevation, azimuth, and distance transforms. The attached appendix illustrates an example of calculating such elevation, azimuth, and distance transforms.

Additionally, the example search engine 120 may prevent the generation of search results that cause the development of inverted geometry by limiting the maximum value of a distance transform, develops search intervals for elevation, azimuth and distance transforms, and removes “locked” vertices and vertices that are found to have small distance transform values. The search intervals for elevation, azimuth and distance form discrete variables that contain known ranges of numbers for each unique unified vertex. These known ranges are searched via commonly known search process the results of which are connected to the analytical processes described herein via an indexing methodology. Based on the methodology described with reference to block 800-804, the search engine 120 creates the geometric search space.

At block 806, the search engine 120 unifies the materials of the design model for the analysis model based on the received material information to create a material searching library. Creating a material search space involves developing a library and controls for the manipulation of design materials for the search process. The controls are developed using indexing methodologies and require that a range of material transform values be produced for each model object in a design model. To create the material search space, the search engine 120 develops a design library of materials for each model object of a design model and contain at least the following material properties: Type, Name, Manufacturer, Brand, Stock Keeping Unit (SKU), Description, Number of layers, Density of layers, Thickness of layers, Emissivity of outer layer, Extinction coefficient of layers, Conductivity of layers, Refractive Index of layers, Embodied energy of layers, Embodied carbon of layers, Patterning of layers, Monetary cost.

For each material, the search engine 120 generates a ranking, which allows more quickly searching of the design library regardless of the range of materials used. In some examples, the search engine determines a value according to Equation 17:

material value=material property A/material property B Equation 17

For example, considering one model object having a clear glass surface, and property A is material density while property B is emissivity, the material values are illustrated in Table 1.

TABLE 1

| Original Material | Material value |
|---|---|
| Clear glass | Clear glass 1 density (i.e. 4)/ |
| | Clear glass 1 emissivity (i.e. 0.1) = 40 |
| Clear glass | Clear glass 2 density (i.e. 3)/ |
| | Clear glass 2 emissivity (i.e. 0.6) = 5 |
| Clear glass | Clear glass 3 density (i.e. 3)/ |
| | Clear glass 3 emissivity (i.e. 0.3) = 10 |
| Clear glass | Clear glass 4 density (i.e. 5)/ |
| | Clear glass 4 emissivity (i.e. 0.4) = 12.5 |

The material value may be used to sort the list, as shown in Table 2.

TABLE 2

| Original Material | Material value |
|---|---|
| Clear glass | 5 (i.e. 3/.0.6) |
| Clear glass | 10 (i.e. 3/0.3) |
| Clear glass | 12.5 (i.e. 5/0.4) |
| Clear glass | 40 (i.e. 4/0.1) |

Alternately, the list may be sorted based on the energy analysis of each material or any other known sorting method.

At block 808, the example search engine 120 unifies the material constraints. As discussed herein, the material constraints may be used to limit the kind of results queried (e.g., same type of material, particular brands of a material, particular product lines from a manufacturer, types of material within the design model palette, etc.).

The example search engine 120 utilizes the user selected material constraints for each surface to constrain the design library of materials as set forth in connection with block 806. For example, a first surface (e.g., wood) may be associated with the “locked” constraint and, thus, would be limited to the default instance of that material type (e.g., no search space). A second surface (e.g., glass) may be constrained to a “type,” which defines the material search space to include all items of that type (e.g., glass). A third surface (e.g., brick) may be “unlocked” such that the material search space may include all items in the material database. A fourth surface (e.g., masonry) may be constrained to “palette” such that the material search space may include all wood, glass, brick, and masonry items.

In some examples, additional information such as function of a model object may be further used to limit a search space. For example, if materials are for interior purposes, such materials may be excluded when applied to exterior surfaces. If materials are for roofing purposes, such materials may be excluded when applied to walls, whether interior or exterior.

In some examples, the materials list includes index numbers associated with the materials within the design library of materials. Accordingly, the material search space may be limited to a particular type, palette, etc. by referencing the index numbers associated with such material. For example, Table 3 illustrates the above example with reference to index number of a design library of materials with 10 materials including wood, glass, brick, and masonry.

TABLE 3

| Original Material | Material constraint | Index |
|---|---|---|
| Wood | Locked | (1) |
| Glass | Type | (4, 5, 6, 7) |
| Brick | Unlocked | (1, 2, 3, 4, 5, |
| | | 6, 7, 8, 9, 10) |
| Masonry | Palette | (1, 2, 3, 4, 5, |
| | | 6, 7, 8, 9, 10) |

The example search engine 120 may create a material transform range for each surface indexed against the design library of materials, as shown in Table 4.

TABLE 4

| Original Material | Material constraint | Material transform range |
|---|---|---|
| Wood | Locked | 1 through 1 |
| Glass | Type | 4 through 7 |
| Brick | Unlocked | 1 through 10 |
| Masonry | Palette | 1 through 10 |

At block 810, the search engine 120 may generate a list of the unified material constraints and may index the list to the respective model objects. For example, the search engine 120 may cross-reference the material constraints list with an ordered list of model objects to produce an indexed listing of which material constraints belong to which model object. As described with reference to block 806-810, the search engine 120 creates the material search space.

At block 812, the example search engine 120 may construct a search matrix based on the geometry search space and the material search space. The search matrix may be an indexed list that fully describes a search space with an indexed set of ranges used to constrain a search.

Blocks 800-812, described above, detail how the example search engine 120 creates a search space. At block 814, the example search engine 120 applies a search algorithm to the generated search space. The search algorithm may be a genetic algorithm utilizing indexing methodologies, a machine learning algorithm, or other alternate searching algorithms. The search algorithm may manipulate the transforms for vertices and material selections that are applied to the analysis model, thereby provide users with variations of his or her design model. In some examples, the search space may be narrowed by removing lesser ranked search results.

At block 816, the example model generator 118 may generate a model based on the search results and perform analysis on the search results similarly to that described with reference to FIG. 7. At block 818, the search engine 120 determines whether the search has converged or met a predefined limit (e.g., according to preferences or constraints). If the search engine 120 determines that the search has not converged or has not met a predefined limit (block 818: NO), control returns to block 800. If control returns to block 800, the search space may be narrowed based on machine learning techniques to improve search processes. If the search engine 120 determines that the search has converged or has met a predefined limit (block 818: YES), the example implementation of block 408 ceases operation.

As described above, multiple types of analysis may be utilized by the models described herein. In some examples, an energy analysis may be presented to a user, through the user interface 112, as an energy profile. The energy profile may include one or more graphs/representations shown and described with reference to FIGS. 9A-9B, textual information, the design profile(s), and any other related data. FIG. 9A illustrates a graphical user interface 900 with a first graph display 902. The first graph display 902 may be a yearly profile for a design model, a model object, or a plurality of model objects. For example, the first graph display 902 may reflect any number of model objects selected by a user. The yearly profile may be plotted with data for each day, month, etc. such that a user may analyze not only the total energy of a particular design, but also the energy in each month. Of course, the first graph display 902 may correspond with other timeframes with any unit of time, such as seconds in a minute, without departing form the scope of this disclosure. A first graph 904 (e.g., the solid line) may correspond to a model object selected or otherwise highlighted by a user, whereas a second graph 906 (e.g., one of the dotted lines) may correspond to a model object not selected by a user.

Alternatively, the second graph 906 may correspond to an alternate version of the selected model object (e.g., with varying geometry and/or material). For example, as described herein, alternate transforms of a design model may be searched for and presented to a user. A selectable interface 908 may allow a user to browse through alternate transforms of the design model. In such an example, as a user browses (e.g., slides right), the second graph 906 may become a solid line and the first graph 904 may become dotted, illustrating user selection of an alternate model object. The entire energy profile may update to reflect such browsing.

A second graph display 910 may be a chronology of multiple iterations of the energy analysis described herein. For example, each time the LI manager 108 determines that the design model changes by a threshold amount and the model generator 118 performs an analysis, an entry may be created in the second graph display 910 illustrating the energy analysis of that design model. As a design model progresses, more entries may be presented in the second graph display 910 to allow a use to see a trend in the energy transmissions of his or her design model as he or she is designing. In some examples, the second graph display 910 may be illustrated as a bar graph. Each bar in the second graph display 910 may be split to show a first energy analysis 912 associated with the design model of a user and a second energy analysis 914 associated with an energy transform of the design model of a user. The energy transform may be a result of the search process described herein and may correspond to a lowest energy transform, a highest energy transform, an average energy transform, etc. Such information shows the difference between the design model of the user and an alternate design, which may be more or less energy efficient.

As described herein, the entries in the second graph display 910 may be correspond to “steps” of a design model. Accordingly, a user may select a bar representation of the entry or “step” to navigate through the chronology of the design model. The chronology may be associated with the energy profiles and design model such that as a user navigates through the “steps” of the design model and energy profile is updated to reflect the selected “step.”

Additional information regarding the analysis described herein may be presented in a textual display 916. As described herein, option 918 allows a user to select, lock, associate, or otherwise update his or her design model with the geometry and/or material information from previous iterations of the design model, the alternate search results, etc.

Additionally, a user may select an information option 920 to obtain even further information. Such further information may include, without limitation, manufacturer information associated with materials used in the design model, design profile analysis, energy profiles, and/or search results. Such information may be associated with the materials used in the design model, design profile analysis, energy profiles, and/or search results generally or upon selection of a particular material by a user (e.g., accepting a browsed search result). In some examples, such further information may be received via a chat interface upon selection of the information option 920.

As illustrated in FIG. 9B, the graphical user interface 900 may be paired with a graphical representation 922 of the design model of a user and/or any selected transforms. Accordingly, as a user browses transforms of a design model (e.g., based on the search process described herein) or versions of the design model (e.g., based on the energy chronology), the graphical representation 922 may update to reflect the browsing.

Table 5, illustrated below, describes an example implementation of the devices, methods, and systems herein with numerical values. Table 5 includes an example series of vertices (e.g., geometry) associated with example surfaces (e.g., model objects) that are unified as described herein. Additionally, Table 5 includes example unified distances based on the example unified vertices constraints. Table 5 includes example materials and example material constraints. Table 5 illustrates example materials indexed to model objects, an example design library of materials, and an example search index (e.g., search space). Table 5 further illustrates example azimuth, elevation, and distance calculations. The vertices of Table 5 correspond to the design model shown and described in FIGS. 10A-10B.

TABLE 5

| Design Model Vertices | | | | |
|---|---|---|---|---|
| | x | y | z | surface |
| 1 | −70.425 | 4.931 | 14 | T |
| 2 | −70.425 | 11.825 | 21 | T |
| 3 | −70.425 | 18.786 | 14 | T |
| 4 | −70.425 | 18.786 | 0 | T |
| 5 | −70.425 | 8.506 | 0 | T |
| 6 | −70.425 | 8.506 | 7 | T |
| 7 | −70.425 | 4.931 | 7 | T |
| 8 | −34.961 | 4.931 | 0 | B |
| 9 | −34.961 | 4.931 | 14 | B |
| 10 | −70.425 | 4.931 | 14 | B |
| 11 | −70.425 | 4.931 | 0 | B |
| Analysis Model Unified Vertices | | | | |
| | x | y | z | |
| 1 | −70.425 | 4.931 | 14 | |
| 2 | −70.425 | 11.825 | 21 | |
| 3 | −70.425 | 18.786 | 14 | |
| 4 | −70.425 | 18.786 | 0 | |
| 5 | −70.425 | 8.506 | 0 | |
| 6 | −70.425 | 8.506 | 7 | |
| 7 | −70.425 | 4.931 | 7 | |
| 8 | −34.961 | 4.931 | 0 | |
| 9 | −34.961 | 4.931 | 14 | |
| 10 | −70.425 | 4.931 | 0 | |

Unified Distances/Constraints

| | | | | Min | Max | Distance | Max Dist. |
|---|---|---|---|---|---|---|---|
| | Measured | Intrinsic | Extrinsic | Dist. | Distance | Interval | Result |
| 1 | 7 | 0.45 | 0 | 0 | 0 | 10 | 0 |
| 2 | 9.848 | 0.45 | 0 | 0 | 0 | 10 | 0 |
| 3 | 9.848 | 0.45 | 0 | 0 | 0 | 10 | 0 |
| 4 | 10.28 | 0.45 | 0 | 0 | 0 | 10 | 0 |
| 5 | 7 | 0.45 | 0 | 0 | 0 | 10 | 0 |
| 6 | 3.575 | 0.45 | 0 | 0 | 0 | 10 | 0 |
| 7 | 3.575 | 0.45 | 0 | 0 | 0 | 10 | 0 |
| 8 | 14 | 0.45 | 0.33 | 0 | 2.079 | 10 | 0.2079 |
| 9 | 14 | 0.45 | 0.33 | 0 | 2.079 | 10 | 0.2079 |
| 10 | 3.575 | 0.45 | 0.33 | 0 | 0.5308875 | 10 | 0.05308875 |
| Design Edges (from Vertices) | | | | | | | |
| T | [1, 2, 3, 4, 5, 6, 7] | | | (i.e. list of | | | |
| | | | | vertices) | | | |
| B | [8, 9, 1, 7, 10] | | | (i.e. list of | | | |
| | | | | vertices) | | | |
| Triangulated Edges | | | | | | | |
| (from Vertices) | | | | | | | |
| t1 | [1, 2, 7] | | | | | | |
| t2 | [2, 3, 4] | | | | | | |
| t3 | [4, 5, 6] | | | | | | |
| t4 | [6, 7, 2] | | | | | | |
| t5 | [2, 4, 6] | | | | | | |
| b1 | [8, 9, 1] | | | | | | |
| b2 | [7, 10, 8] | | | | | | |
| b3 | [8, 1, 7] | | | | | | |

| Material Types | | |
|---|---|---|
| 1 | Glass | (i.e. Index 1 = Glass) |
| 2 | Wood | (i.e. Index 2 = Wood) |
| Materials/Material Constraints for individual surfaces | | |
| t1 | Glass | Locked |
| t2 | Glass | Locked |
| t3 | Glass | Locked |
| t4 | Glass | Locked |
| t5 | Glass | Locked |
| b1 | Wood | Material Type |
| b2 | Wood | Material Type |
| b3 | Wood | Material Type |

| Material Types Indexed to Surfaces | | | | |
|---|---|---|---|---|
| T | [1, 1, 1, 1, 1] | (i.e. t1 = 1, t2 = 1 t3 = 1 | | |
| | | . . .) | | |
| B | [2, 2, 2] | (i.e. b1 = 2, b2 = 2 . . .) | | |
| Design Library of Materials | | | | |
| | Material | | Default | . . . Other |
| | Type | Type No | Item | Properties |
| 1 | Concrete | 1 | Yes | (i.e. Cost, |
| | | | | Embodied |
| | | | | Energy, etc . . .) |
| 2 | Glass | 1 | No | . . . |
| 3 | Glass | 2 | Yes | . . . |
| 4 | Glass | 3 | No | . . . |
| 5 | Metal | 1 | Yes | . . . |
| 6 | Wood | 1 | No | . . . |
| 7 | Wood | 2 | Yes | . . . |
| 8 | Wood | 3 | No | . . . |
| 9 | Wood | 4 | No | . . . |

Search Index (Full format)

| General | [surface materials, geometry distance (d), geometry elevation (e), geometry azimuth (a)] | |
|---|---|---|
| | [Materials] | [Geometry] |
| Index type | [t1, t2, t3, t4, t5, b1, b2, b3] | [d1, d2, d3, . . ., e1, e2, e3, . . ., a1, a2, a3, . . .] |
| Low | [2, 2, 2, 2, 2, 6, 6, 6] | [0, 0, 0, 0, 0, 0, 0, 0, 0, 0, −10, −10, −10, −10, −10, −10, −10, −10, −10, −10, |
| Constraint | | 0, 0, 0, 0, 0, 0, 0, 0, 0, 0] |
| High | [2, 2, 2, 2, 2, 9, 9, 9] | [10, 10, 10, 10, 10, 10, 10, 10, 10, 10, 10, 10, 10, 10, 10, 10, 10, |
| Constraint | | 10, 10, 10, 10, 10, 10, 10, 10, 10, 10, 10, 10, 10] |
| Search Index (Narrowed) | | |
| Index type | [b1, b2, b3] | [d8, d9, d10, e8, e9, e10, a8, |
| | | a9, a10] |
| Low | [6, 6, 6] | [0, 0, 0, −10, −10, 10, 0, 0, 0] |
| Constraint | | |
| High | [9, 9, 9] | [10, 10, 10, 10, 10, 10, 10, 10, 10] |
| Constraint | | |
| Search Index | | |
| Index type | [b1, b2, b3, d8, d9, d10, e8, e9, e10, a8, a9, a10] | |
| Low | [6, 6, 6, 0, 0, 0, −10, −10, −10, 0, 0, 0] | |
| Constraint | | |
| High | [9, 9, 9, 10, 10, 10, 10, 10, 10, 10, 10, 10] | |
| Constraint | | |

Method for calculating actual distance, elevation and azimuth to apply in transform:
Integer based search produces a list of integers (X) that range between low and high constraints and are
indexed similarly, i.e. [X1, X2, X3, X4, X5, X6, X7, X8, X9, X10, X11, X12]

| The calculation of distances occur as: | |
|---|---|
| d8 = | X4 * Max Dist. Result 8 (i.e. X4 * 0.2079) |
| d9 = | X5 * Max Dist. Result 9 (i.e. X5 * 0.2079) |
| d19 = | X6 * Max Dist. Result 10 (i.e. X6 * 0.053) |
| The calculation of elevations occur as: | |
| e8 = | asin(X7/10) |
| e9 = | asin(X8/10) |
| e10 = | asin(X9/10) |
| The calculation of azimuths occur as: | |
| a8 = | X10 * 2 pi/10 |
| a9 = | X11 * 2 pi/10 |
| a10 = | X12 * 2 pi/10 |

The material transform occurs directly such that an integer value X1 or X2 (etc.) would refer to the library
index for the selected material
The default value for a material, will be the default value assigned by the library unless a user has selected
a material produced by an analysis result

The above discussed embodiments are simply examples, and modifications may be made as desired for different implementations. For example, steps and/or components may be subdivided, combined, rearranged, removed, and/or augmented; performed on a single device or a plurality of devices; performed in parallel, in series; or any combination thereof. Additional features may be added.

1. A method comprising:
receiving, by a computing device, material information, geometry information, location information, and constraint information associated with a design model; and
generating, by the computing device and based on the material information, geometry information, the location information, and the constraint information, an energy analysis model associated with energy transmissions for the design model, wherein the energy transmissions are based on energy transmissions through surfaces of a plurality of model objects that collectively form the design model.

2. The method of claim 1, further comprising packaging the energy transmissions into an energy profile.

3. The method of claim 1, wherein the geometry information comprises at least one of area data, normal data, or vertex data associated with one or more model objects in the design model, and wherein the material information comprises a material associated with the one or more model objects in the design model.

4. The method of claim 1, wherein the receiving of the material information and the geometric information occurs in response to:
determining, at a first time, a first list of model objects within the design model;
determining, at a second time, a second list corresponding to model objects that match, are altered, or are new in view of the first list of model objects;
quantifying a variance based on the first list and the second list; and
determining that the quantified variance meets or exceeds a threshold.

5. The method of claim 1, wherein the material information comprises a first material, the geometry information comprises a first geometry, the energy analysis model is a first energy analysis model, and the energy transmissions are first energy transmissions, the method further comprising:
locating at least one of a second material different from the first material or a second geometry different from the first geometry;
generating a second energy analysis model based on the at least one of the second material or the second geometry and based on the location information and the constraints; and
determining, based on the generated second energy analysis model, second energy transmissions for the design model.

6. The method of claim 1, wherein the material information is first material information, the geometry information is first geometry information, the energy analysis model is a first energy analysis model, and the energy transmissions are first energy transmissions, the method further comprising:
generating a second energy analysis model based on received second material information and second geometry information;
determining, based on the generated second energy analysis model, second energy transmissions for the design model; and
generating, based on the first energy transmissions and the determined second energy transmissions, an energy chronology.

7. The method of claim 6, further comprising causing the first energy transmissions and the second energy transmissions to be presented to a user.

8. A computer-implemented method comprising:
receiving a design profile comprising a first material or a first geometry associated with a design model;
generating a first energy analysis model based on the design profile;
determining, based on the generated first energy analysis model, first energy transmissions for the design model;
locating at least one of a second material different from the first material or a second geometry different from the first geometry;
generating a second energy analysis model based on the design profile and based on the at least one of the second material or the second geometry; and
determining, based on the generated second energy analysis model, second energy transmissions for the design model.

9. The method of claim 8, further comprising:
presenting the second energy transmissions to a user;
receiving an indication that the user selected the second energy transmissions; and
associating the at least one of the second material or the second geometry with the design profile corresponding to the design model, wherein the second material comprises an identifier of a manufacturer.

10. The method of claim 8, wherein the locating of the at least one of the second material different from the first material or the second geometry different from the first geometry comprises:
determining a material constraint defining a first search space for materials;
determining a geometric constraint defining a second search space for geometries; and
locating the at least one of the second material or the second geometry based on the first search space and the second search space.

11. The method of claim 8, further comprising packaging the determined first energy transmissions into a first energy profile and the determined second energy transmission into a second energy profile.

12. The method of claim 8, wherein the design profile is a first design profile, the method further comprising:
generating a third energy analysis model based on a received second design profile;
determining, based on the generated third energy analysis model, third energy transmissions for the design model; and
generating, based on the determined first energy transmissions and the determined third energy transmissions, an energy chronology.

13. The method of claim 8, wherein the receiving of the design profile occurs in response to:
determining, at a first time, a first list of model objects within the design model;
determining, at a second time, a second list corresponding to model objects that match, are altered, or are new in view of the first list of model objects;
quantifying a variance based on the first list and the second list; and
determining that the quantified variance meets or exceeds a threshold.

14. The method of claim 8, wherein at least one of the first energy transmissions for the design model or the second energy transmissions for the design model is based on an aggregate of energy transmissions through surfaces of model objects that collectively form the design model.

15. A method comprising:
receiving, by a computing device remote from a user device, a first design profile associated with a design model generated at the user device;
generating, by the computing device, a first energy analysis model based on the first design profile;
determining, by the computing device and based on the generated energy analysis model, first energy transmissions for the design model;
in response to receiving a second design profile, generating a second energy analysis model based on the second design profile;
determining, based on the generated second energy analysis model, second energy transmissions for the design model; and
generating, based on the determined first energy transmissions and the determined second energy transmissions, an energy chronology.

16. The method of claim 15, further comprising packaging the determined first energy transmissions and the determined second energy transmissions into energy profiles.

17. The method of claim 15, wherein the receiving of the first design profile occurs in response to:
determining, at a first time, a first list of model objects within the design model;
determining, at a second time, a second list corresponding to model objects that match, are altered, or are new in view of the first list of model objects;
quantifying a variance based on the first list and the second list; and
determining that the quantified variance meets or exceeds a threshold.

18. The method of claim 15, wherein at least one of the first energy transmissions for the design model or the second energy transmissions for the design model is based on an aggregate of energy transmissions through surfaces of model objects that collectively form the design model.

19. The method of claim 15, wherein the first design profile comprises a first material or a first geometry, the method further comprising:
locating at least one of a second material different from the first material or a second geometry different from the first geometry;
generating a third energy analysis model based on the first design profile and based on the at least one of the second material or the second geometry;
determining, based on the generated third energy analysis model, third energy transmissions for the design model.

20. The method of claim 19, further comprising causing the first energy transmissions, the second energy transmissions, and the third energy transmissions to be presented at the user device.
